(19) United States
(12) Patent Application Publication
(10) Pub. No.: US 2010/0308365 A1
(43) Pub. Date: Dec. 9, 2010

(54) COMPOUND SEMICONDUCTOR LIGHT EMITTING DIODE

(75) Inventors: Kyosuke Masuya, Ichihara-shi (JP); Ryouichi Takeuchi, Chichibu-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 12/865,331

(22) PCT Filed: Feb. 6, 2009
(86) PCT No.: PCT/JP2009/052063

§ 371 Date: Jul. 29, 2010

(30) Foreign Application Priority Data
Feb. 7, 2008 (JP) 2008-027720
Jan. 29, 2009 (JP) 2009-018395

(51) Int. Cl. H01L 33/30; H01L 33/42

(52) U.S. Cl. 257/98; 257/99; 257/103; 257/E33.023; 257/E33.064; 257/E33.066; 257/E33.075

(57) ABSTRACT

Disclosed is a compound semiconductor light emitting diode 101 including: a device structure portion 10 formed on a transparent base portion 25, the device structure portion 10 including a compound semiconductor layer having a first conductivity type, a light emitting layer 13 made of mixed crystals of aluminum phosphide gallium indium (having a composition of (Al_{X}Ga_{1-X})_{0.5}In_{0.5}P; 0≦X<1), and a compound semiconductor layer having a conductivity type opposite to the first conductivity type; and a first ohmic electrode 1 formed on the device structure portion 10, wherein the second ohmic electrode 5 is formed on the opposite side to the transparent base portion 25, the metal coating film 6 is formed to cover the second ohmic electrode 5, and a metallic pedestal portion 7 covering the metal coating film 6 is formed to electrically connect to the second ohmic electrode 5.

### TECHNICAL FIELD

The present invention relates to a compound semiconductor light emitting diode including a light emitting layer made of AlGaInP, and particularly, to a compound semiconductor light emitting diode having a large device size, an excellent heat dissipation capability, and a high luminance.

The present invention claims the benefits of priorities of Japanese Patent Application Nos. 2008-027720 and 2009-018395, filed on Feb. 7, 2008, and Jan. 29, 2009, respectively, the entire contents of which are hereby incorporated by reference.

### BACKGROUND ART

As a light emitting diode (LED) which emits a visible light having a red color to a yellow-green color, for example, a compound semiconductor light emitting diode having a light emitting layer made of aluminum gallium indium phosphide (a composition of (Al_{X}Ga_{1-X})_{Y}In_{1-Y}P; 0≦X≦1, 0<Y≦1) is known in the art. Generally, a device structure portion including a light emitting portion as a light emitting layer composed of (Al_{X}Ga_{1-X})_{Y}In_{1-Y}P; (0≦X≦1, 0<Y≦1) is formed on a single crystal substrate made of gallium arsenide (GaAs) whose lattices match with a III-V group compound layer or the like used as the device structure.

Since the light having a wavelength emitted from the light emitting layer having a composition of (Al_{X}Ga_{1-X})_{Y}In_{1-Y}P; 0≦X≦1, 0<Y≦1) is absorbed in the GaAs, there is disclosed a technology for configuring a high luminance transparent material bonding type compound semiconductor LED by further bonding a support member made of an optically transparent material to the light emitting portion or the device structure portion (e.g., refer to Patent documents 1 to 5). According to the technologies disclosed in Patent document 1 to 5, it is possible to improve the mechanical strength of the compound semiconductor light emitting diode by bonding a support member made of a transparent material having an excellent mechanical strength.

As disclosed in Patent documents 6 and 7, in a compound semiconductor light emitting diode having a structure in which a pair of electrodes are provided in upper and lower sides of the device (commonly called an upper-and-lower electrode structure), there is disclosed a method of improving the extraction efficiency of the light emitted from the device structure portion to the outer side of the device by inclining the side face of the support member (an inclined side face) so that a high luminance compound semiconductor visible light emitting diode can be obtained.

[Patent document 1] Japanese Patent Publication No. 3230638

[Patent document 2] Japanese Unexamined Patent Application, First publication No. 6-302857

[Patent document 3] Japanese Unexamined Patent Application, First publication No. 2002-246640

[Patent document 4] Japanese Patent Publication No. 2588849

[Patent document 5] Japanese Unexamined Patent Application, First publication No. 2001-57441

[Patent document 6] U.S. Patent Application, Publication No. 2003/0127654

[Patent document 7] U.S. Pat. No. 6,229,160

### DISCLOSURE OF INVENTION

### Problems to be Solved by the Invention

In the conventional compound semiconductor light emitting diodes using GaAs as the substrate, the GaAs is optically opaque for the visible light emitted from the device structure portion.

Therefore, it fails to sufficiently improve the extraction efficiency of the light emitted to the outer side of the device, and it is not an appropriate structure for obtaining a high luminance compound semiconductor visible light emitting diode. In addition, since the GaAs used as the substrate is not a compound semiconductor material capable of providing an excellent mechanical strength, it is difficult to sufficiently use the GaAs as the support member for providing a compound semiconductor visible light emitting diode having high mechanical strength.

Meanwhile, in a compound semiconductor visible light emitting diode in which the side face of the lower portion of the device is inclined, and the vertical cross section has an inverted triangular shape in order to improve the light extraction efficiency of the light emitting to the outer side, the bottom area of the lower face of the light emitting diode is reduced, and the center is located over the device, so that, the device may frequently fall down. Therefore, since it is difficult to erect the device, and the device easily falls down even when the compound semiconductor light emitting diode having such a cross-sectional shape is fixed to the mount panel, it is not appropriately mounted. Furthermore, it degrades the product yield of the industrial production when a lamp or the like using a light emitting diode (LED) chip is manufactured.

Moreover, in a compound semiconductor light emitting diode having the GaAs substrate, the thermal conductivity of GaAs occupying most of the volume of the light emitting diode is 0.54 Wcm⁻¹K⁻¹, which is significantly low compared to a metal material (refer to “III-V group compound semiconductor”, published by BAIFUKAN Co., Ltd., 1st Edition, page 148, by Isamu AKASAKI, May 20, 1994). Therefore, in a large-sized light emitting diode necessary to flow a large current, it is difficult to sufficiently radiate the heat generated by operating the device to the outer side and avoid a variation in the wavelength of the emitted light caused by the heat. In addition, since the side face is inclined, and the bottom area of the lower face of the light emitting diode is small, for example, the area making contact with the mount panel also used as a heat dissipation plate is reduced. Therefore, it is difficult to suppress the temperature of the device from increasing.

The present invention has been made to solve the aforementioned problems and provides a high luminance compound semiconductor light emitting diode that has an excellent heat dissipation capability and can be readily mounted.

### Means for Solving the Problems

In order to achieve the aforementioned objects, the present invention employs the following configuration.

(1) According to a first embodiment of the present invention, there is provided a compound semiconductor light emitting diode including: a device structure portion formed on one surface of a transparent base portion made of an optically transparent material, the device structure portion including a compound semiconductor layer having a first conductivity type, a light emitting layer made of mixed crystals of aluminum phosphide.gallium.indium (having a composition of (Al_{X}Ga_{1-X})_{0.5}In_{0.5}P: 0≦X<1) and having a first conductivity type or a conductivity type opposite to the first conductivity type, and a compound semiconductor layer having a conductivity type opposite to the first conductivity type; and a first ohmic electrode formed on the device structure portion and having a single polarity, wherein a second ohmic electrode is formed on an opposite side of the one surface of the transparent base portion, a metal coating film is formed to cover the second ohmic electrode, and a metallic pedestal portion covering the metal coating film is formed to electrically connect to the second ohmic electrode.

(2) According to a second embodiment of the present invention, in the compound semiconductor light emitting diode according to paragraph (1), a mesa having a vertical cross-sectional shape of an inverted isosceles trapezoidal shape is formed on an opposite side of the one surface of the transparent base portion, the mesa has a lower bottom face and an inclined side face, a second ohmic electrode is formed on the lower bottom face, and a metal coating film is formed to cover the second ohmic electrode, the lower bottom face, and the inclined side face.

(3) According to a third embodiment of the present invention, in the compound semiconductor light emitting diode according to paragraph (1) or (2), the transparent base portion is made of a growth base layer.

(4) According to a fourth embodiment of the present invention, in the compound semiconductor light emitting diode according to paragraph (1) or (2), the transparent base portion includes a growth base layer and a transparent bonding substrate bonded to the growth base layer.

(5) According to a fifth embodiment of the present invention, in the compound semiconductor light emitting diode according to paragraph (4), the transparent bonding substrate has the same conductivity type as that of the growth base layer.

(6) According to a sixth embodiment of the present invention, in the compound semiconductor light emitting diode according to paragraph (4) or (5), a face of the transparent bonding substrate, bonded to the growth base layer, is a mirror-polished face having a roughness of 0.10 to 0.20 nm as a root-mean-square value.

(7) According to a seventh embodiment of the present invention, in the compound semiconductor light emitting diode according to any one of paragraphs (2) to (6), an inclination angle of the inclined side face is equal to or larger than 10° and equal to or smaller than 45° with respect to a normal line to one surface of the transparent base portion.

(8) According to an eighth embodiment of the present invention, in the compound semiconductor light emitting diode according to any one of paragraphs (2) to (7), the inclined side face is a roughened face having unevenness equal to or larger than 0.1 μm and equal to or smaller than 10 μm as a height difference.

(9) According to a ninth embodiment of the present invention, in the compound semiconductor light emitting diode according to any one of paragraphs (2) to (8), the lower bottom face is a roughened face having unevenness equal to or larger than 0.1 μm and equal to or smaller than 10 μm as a height difference.

(10) According to a tenth embodiment of the present invention, in the compound semiconductor light emitting diode according to any one of paragraphs (1) to (9), an opposite side of the one surface of the transparent base portion has a plurality of mesas.

(11) According to an eleventh embodiment of the present invention, in the compound semiconductor light emitting diode according to paragraph (10), a plurality of the mesas is symmetrically positioned with respect to a center of the transparent base portion as seen in a top plan view.

(12) According to a twelfth embodiment of the present invention, in the compound semiconductor light emitting diode according to any one of paragraphs (1) to (11), a plurality of the second ohmic electrodes is provided on the lower bottom face.

(13) According to a thirteenth embodiment of the present invention, in the compound semiconductor light emitting diode according to any one of paragraphs (1) to (12), the metal coating film is made of a material different from the second ohmic electrode.

(14) According to a fourteenth embodiment of the present invention, in the compound semiconductor light emitting diode according to any one of paragraphs (1) to (13), the metal coating film has a reflectance equal to or larger than 80% with respect to light irradiated from the device structure portion and is made of a material containing any one of silver, aluminum, or platinum.

(15) According to a fifteenth embodiment of the present invention, in the compound semiconductor light emitting diode according to any one of paragraphs (1) to (14), the metal coating film is formed to cover an opposite side of the one surface of the transparent base portion.

(16) According to a sixteenth embodiment of the present invention, in the compound semiconductor light emitting diode according to any one of paragraphs (1) to (15), the pedestal portion has a thermal conductivity equal to or higher than 200 W/mK and is made of a material containing any one of copper, aluminum, gold, or platinum.

(17) According to a seventeenth embodiment of the present invention, in the compound semiconductor light emitting diode according to paragraph (16), the pedestal portion has a thermal conductivity equal to or higher than 200 W/mK and is made of a material containing a layer structure of copper or molybdenum.

(18) According to an eighteenth embodiment of the present invention, in the compound semiconductor light emitting diode according to paragraphs (16) or (17), a thermal expansion rate of the pedestal portion is within ±20% of a thermal expansion rate of the compound semiconductor layer and is made of a material containing a layer structure of copper or molybdenum.

(19) According to a nineteenth embodiment of the present invention, in the compound semiconductor light emitting diode according to any one of paragraphs (16) to (18), a thermal expansion rate of the pedestal portion is 3 to 7 ppm/K and is made of a material containing a layer structure of copper or molybdenum.

(20) According to a twentieth embodiment of the present invention, in the compound semiconductor light emitting diode according to any one of paragraphs (1) to (19), a transparent oxide layer is inserted between the metal coating film and the transparent base portion.

(21) According to a twenty first embodiment of the present invention, in the compound semiconductor light emitting diode according to paragraph (20), the transparent oxide layer has conductivity.

### EFFECTS OF THE INVENTION

According to the aforementioned configurations, it is possible to provide a high luminance compound semiconductor light emitting diode that has a high heat dissipation capability and can be readily mounted.

According to a first embodiment of the present invention, since the device structure portion is formed on one surface of the transparent base portion, the light emitted from the device structure portion is transmitted through the transparent base portion and then reflected to the front direction at the metal coating film. Therefore, it is possible to provide a compound semiconductor light emitting diode having an excellent light output capability in the front direction (external view direction).

According to a first embodiment of the present invention, since the metallic pedestal portion is attached to the transparent base portion through the metal coating film, it is possible to address poor mounting stability of the light emitting diode of the related art which is difficult to autonomously stand erect because a bottom face area is reduced by cutting out the side face. Meanwhile, it is possible to stably provide the compound semiconductor light emitting diode having an excellent heat dissipation capability.

According to a second embodiment of the present invention, since the device structure portion is formed on one surface of the transparent base portion, and the mesa is provided to face the device structure portion on an opposite side of the one surface of the transparent base portion, the light output from the device structure portion is transmitted through the transparent base portion, and then reflected in the front direction at the metal coating film covering the mesa. Therefore, it is possible to provide a compound semiconductor light emitting diode having an excellent light output capability in the front direction (external view direction).

According to a second embodiment of the present invention, since the mesa having an inverted isosceles trapezoidal cross-sectional shape as a reflection mirror capable of effectively reflecting the light emitted from the device structure portion into the front direction (external view direction) is provided on an opposite side of the one surface of the transparent base portion, it is possible to provide a high luminance compound semiconductor light emitting diode.

According to a second embodiment of the present invention, since the metallic pedestal portion is attached to the transparent base portion through the metal coating film, it is possible to address poor mounting stability of the light emitting diode of the related art which is difficult to autonomously stand erect because a bottom face area is reduced by cutting out the side face. Meanwhile, it is possible to stably provide the compound semiconductor light emitting diode having an excellent heat dissipation capability.

According to a third embodiment of the present invention, since the transparent base portion includes the growth base layer, it is possible to use the growth base layer not only as a pedestal layer for maintaining the device structure portion but also to conveniently form the mesa in an opposite side of the one surface of the transparent base portion.

According to a fourth embodiment of the present invention, since the transparent base portion includes the growth base layer and the transparent bonding substrate bonded to the growth base layer, it is possible to form a thicker transparent base portion in comparison with the transparent base layer including only the growth base layer and contribute to the high mechanical strength of the compound semiconductor light emitting diode.

According to a fifth embodiment of the present invention, since the transparent bonding substrate having the same conductivity type as that of the growth base layer is bonded to the growth base layer, it is possible to appropriately flow the device operation electric current for operating the light emitting diode to/from the first ohmic electrode provided in the device structure portion via the second ohmic electrode provided in the lower bottom face of the mesa electrically connected to the metallic pedestal portion. As a result, it is possible to provide the compound semiconductor light emitting diode having a double-sided electrode structure and provide a compound semiconductor light emitting diode having an excellent heat dissipation capability, a high luminance, and a high mountability.

According to a sixth embodiment of the present invention, since the face of the transparent bonding substrate bonded to the growth base layer is mirror-polished to have a roughness of 0.10 nm to 0.20 nm as a root-mean-square value, it is possible to strongly bond the transparent bonding substrate to the growth base layer. Therefore, it is possible to provide a compound semiconductor light emitting diode having an excellent mechanical strength.

According to a seventh embodiment of the present invention, since the inclination angle of the inclined side face is equal to or larger than 10° and equal to or smaller than 45° with respect to a normal line of one surface of the transparent base portion, it is possible to effectively output the light emitted from the device structure portion to the front direction (external view direction) of the light emitting diode using the metal coating film. As the inclination angle of the inclined side face decreases, it is possible to form a reflection mirror having a cup-like cross-sectional shape by reducing the horizontal cross-sectional area. It is possible to provide a high luminance compound semiconductor light emitting diode having excellent light output capability to the external side of the device.

According to an eighth embodiment of the present invention, since the inclined side face is roughened to have unevenness having a height difference equal to or larger than 0.1 μm and equal to or smaller than 10 μm, it is possible to increase the surface area of the metal coating film which is mounted in the inclined side face and reflects the light emitted from the device structure portion to the front direction (device view direction) of the light emitting diode. Therefore, it is possible to provide a high luminance compound semiconductor light emitting diode having an excellent light output capability to the outer side of the device.

According to a ninth embodiment of the present invention, since the lower bottom face is roughened to have unevenness having a height difference equal to or larger than 0.1 μm and equal to or smaller than 10 μm, the metal coating film can be formed to have a larger surface area for reflecting the light transmitted through the transparent base portion and incident on the lower bottom face from the device structure portion. Therefore, it is possible to provide a high luminance compound semiconductor light emitting diode that can output light to the outer side of the device with high efficiency.

According to a tenth embodiment of the present invention, since a plurality of mesas is provided on an opposite side of the one surface of the transparent base portion, it is possible to arrange a plurality of reflection mirrors including the metal coating film inside the light emitting diode. Therefore, it is possible to provide a high luminance compound semiconductor light emitting diode.

For example, it is possible to provide a high luminance compound semiconductor light emitting diode even in a large-sized light emitting diode having a planarly wide device structure portion and a length of 1 mm.

According to an eleventh embodiment of the present invention, since a plurality of the mesas is symmetrically arranged with respect to the center of the transparent base portion as seen in a plan view, it is possible to provide a high luminance compound semiconductor light emitting diode in which the intensity of the output light is symmetric.

According to a twelfth embodiment of the present invention, since a plurality of the second ohmic electrodes is arranged on the lower bottom face, it is possible to uniformly diffuse the device operation electric current fed from the pedestal portion across the device structure portion and provide a compound semiconductor light emitting diode having an excellent regularity of the light emission intensity.

According to a thirteenth embodiment of the present invention, since the metal coating film is made of a material different from the second ohmic electrode, it is possible to form a reflection mirror made of a metallic material having a higher reflectance for the light emitted from the device structure portion than that of a material of the second ohmic electrode. Therefore, it is possible to contribute to a high luminance compound semiconductor light emitting diode.

According to a fourteenth embodiment of the present invention, since the metal coating film has a reflectance equal to or higher than 80% for the light emitted from the device structure portion and is made of a material containing any one of silver, aluminum, or platinum, it is possible to effectively reflect the light emitted from the device structure portion. Therefore, it is possible to provide a high luminance compound semiconductor light emitting diode.

According to a fifteenth embodiment of the present invention, since the metal coating film is formed to cover an opposite side of one surface of the transparent base portion, it is possible to reflect the light emitted from the device structure portion and incident on the circumferential area of the mesa to the outer side of the device. Therefore, it is possible to provide a high luminance compound semiconductor light emitting diode.

According to a sixteenth embodiment of the present invention, since the pedestal portion is made of a material having a thermal conductivity equal to or higher than 200 W/mK and containing any one of copper, aluminum, gold, or platinum, it is possible to provide a compound semiconductor light emitting diode having an excellent heat dissipation capability.

According to a seventeenth embodiment of the present invention, since the pedestal portion is made of a material having a thermal conductivity equal to or higher than 200 W/mK and including a layer structure of copper and molybdenum, it is possible to provide a compound semiconductor light emitting diode having an excellent heat dissipation capability.

According to an eighteenth embodiment of the present invention, since the pedestal portion is made of a material having a layer structure including copper and molybdenum, and the thermal expansion rate of the pedestal portion is preferably set to ±20% of the thermal expansion rate of the compound semiconductor layer, it is possible to readily manufacture the compound semiconductor light emitting diode having an excellent heat dissipation capability with high accuracy.

According to a nineteenth embodiment of the present invention, since the pedestal portion is made of a material including a layer structure of copper and molybdenum, and the thermal expansion rate of the pedestal portion is set to 3 to 7 ppm/K, it is possible to readily manufacture the compound semiconductor light emitting diode having an excellent heat dissipation capability with high accuracy.

According to a twentieth embodiment of the present invention, since the transparent oxide layer is inserted between the metal coating film and the transparent base portion, it is possible to prevent the reflectance degradation caused by the reaction between the metal coating film and the transparent base portion. Therefore, it is possible to provide a high luminance compound semiconductor light emitting diode.

According to a twenty first embodiment of the present invention, since the transparent oxide layer is conductive, electric connection between the metal coating film and the ohmic electrode can be obtained. Therefore, unlike the case where an insulative transparent oxide layer is used, it is not necessary to selectively remove the transparent oxide layer corresponding to the ohmic electrode and thus possible to simplify the manufacturing process.

### BRIEF DESCRIPTION OF DRAWINGS

FIG. 1A is a schematic plan view illustrating a light emitting diode according to an embodiment of the present invention.

FIG. 1B is a schematic cross-sectional plan view along line A-A′ of FIG. 1A for illustrating a light emitting diode according to an embodiment of the present invention.

FIG. 2 is a schematic cross-sectional plan view along line B-B′ of FIG. 1B for illustrating a light emitting diode according to an embodiment of the present invention.

FIG. 3 is a schematic plan view illustrating a light emitting diode according to an embodiment of the present invention.

FIG. 4 is a schematic plan view illustrating a light emitting diode according to an embodiment of the present invention.

FIG. 5 is a schematic plan view illustrating a light emitting diode according to an embodiment of the present invention.

FIG. 6 is a schematic plan view illustrating a light emitting diode according to an embodiment of the present invention.

FIG. 7 is a schematic plan view illustrating a light emitting diode according to an embodiment of the present invention.

FIG. 8 is a schematic plan view illustrating a light emitting diode according to an embodiment of the present invention.

FIG. 9 is a schematic plan view illustrating a light emitting diode according to an embodiment of the present invention.

FIG. 10 is a schematic plan view illustrating a light emitting diode according to an embodiment of the present invention.

FIG. 11 is a schematic plan view illustrating a light emitting diode according to an embodiment of the present invention.

FIG. 12A is a cross-sectional process diagram illustrating a method of manufacturing a light emitting diode according to an embodiment of the present invention.

FIG. 12B is a cross-sectional process diagram illustrating a method of manufacturing a light emitting diode according to an embodiment of the present invention.

FIG. 12C is a cross-sectional process diagram illustrating a method of manufacturing a light emitting diode according to an embodiment of the present invention.

FIG. 12D is a cross-sectional process diagram illustrating a method of manufacturing a light emitting diode according to an embodiment of the present invention.

FIG. 13A is a cross-sectional process diagram illustrating a method of manufacturing a light emitting diode according to an embodiment of the present invention.

FIG. 13B is a cross-sectional process diagram illustrating a method of manufacturing a light emitting diode according to an embodiment of the present invention.

FIG. 13C is a cross-sectional process diagram illustrating a method of manufacturing a light emitting diode according to an embodiment of the present invention.

FIG. 13D is a cross-sectional process diagram illustrating a method of manufacturing a light emitting diode according to an embodiment of the present invention.

FIG. 13E is a cross-sectional process diagram illustrating a method of manufacturing a light emitting diode according to an embodiment of the present invention.

FIG. 14 is a cross-sectional process diagram illustrating a method of manufacturing a light emitting diode according to an embodiment of the present invention.

FIG. 15 is a schematic cross-sectional view illustrating a light emitting diode according to an embodiment of the present invention.

FIG. 16 is a schematic cross-sectional view illustrating a light emitting diode according to an embodiment of the present invention.

FIG. 17 is a schematic cross-sectional view illustrating a light emitting diode according to an embodiment of the present invention.

FIG. 18A is a schematic cross-sectional view illustrating a light emitting diode according to an embodiment of the present invention.

FIG. 18B is a schematic cross-sectional plan view along line G-G′ of FIG. 18A for illustrating a light emitting diode according to an embodiment of the present invention.

FIG. 19A is a schematic cross-sectional view illustrating a light emitting diode according to an embodiment of the present invention.

FIG. 19B is a schematic cross-sectional plan view along line H-H′ of FIG. 19A for illustrating a light emitting diode according to an embodiment of the present invention.

FIG. 20A is a schematic cross-sectional view illustrating a light emitting diode according to an embodiment of the present invention.

FIG. 20B is a schematic cross-sectional plan view along line I-I′ of FIG. 20A for illustrating a light emitting diode according to an embodiment of the present invention.

The reference symbols shown in these figures are defined as follows:

1 . . . first ohmic electrode, 2 . . . compound semiconductor layer, 3 . . . p-type GaP layer, 3a . . . growth initiation surface, 3b . . . other face, 3c . . . side face, 4 . . . transparent bonding substrate, 4a . . . bonding surface, 4b . . . lower bottom face, 4c . . . side face, 4d . . . inclined side face, 5 . . . second ohmic electrode, 6 . . . metal coating film, 7 . . . pedestal portion, 7c . . . side face, 8 . . . trench, 10 . . . device structure portion, 10a . . . face in the front direction, 10b . . . opposite side face, 11 . . . contact layer, 11a . . . face in the front direction, 12 . . . lower clad layer, 13 . . . light emitting layer, 14 . . . upper clad layer, 21 . . . semiconductor substrate, 22 . . . first buffer layer, 25 . . . transparent base portion, 30 . . . epitaxial wafer, 31 . . . bonding substrate, 33 . . . n-type electrode formation substrate, 44 . . . p-type electrode formation substrate, 45 . . . trench formation substrate, 46 . . . metal coating film formation substrate, 47 . . . pedestal portion formation substrate, 88 . . . transparent oxide layer, 90 . . . mesa, 90a . . . upper bottom face, 90b . . . lower bottom face, 90d . . . inclined side face, 101, 102, 103, 104, 105, 145 . . . light emitting diode, 147, 148 . . . light emitting diode, f . . . front direction (light output direction), d . . . height, α . . . inclination angle, v . . . normal line.

### BEST MODE FOR CARRYING OUT THE INVENTION

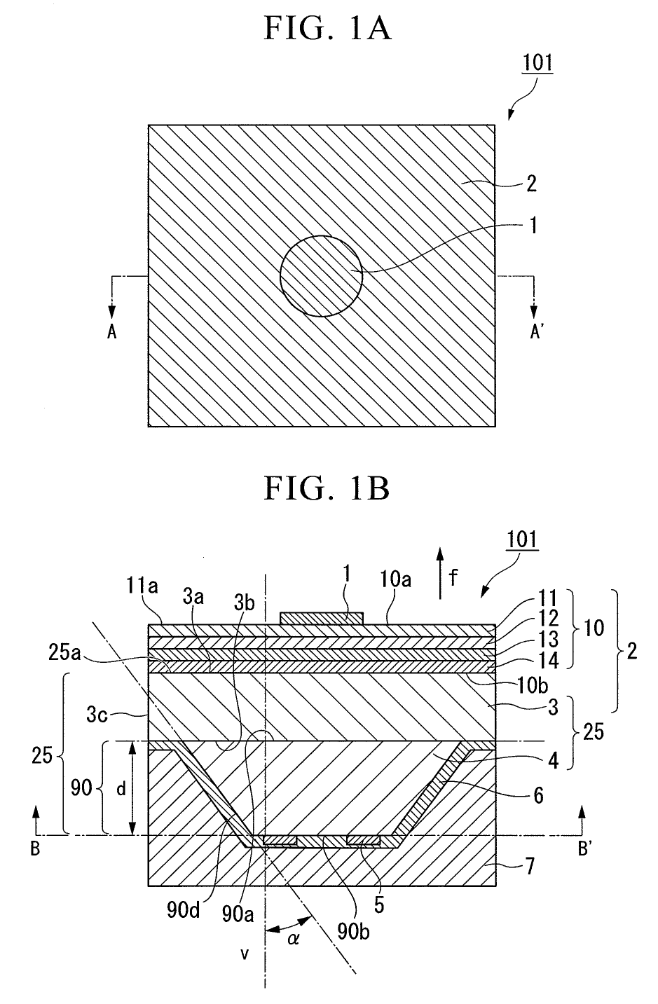

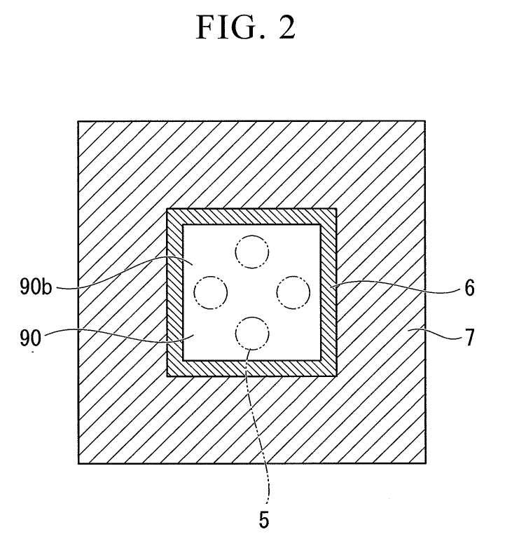

Hereinafter, an embodiment of the present invention will be described with reference to FIGS. 1A, 1B, and 2.

### First Embodiment

FIGS. 1A, 1B, and 2 schematically illustrate a compound semiconductor light emitting diode 101 according to a first embodiment of the present invention. FIG. 1A is a schematic plan view illustrating a compound semiconductor light emitting diode 101. FIG. 1B is a schematic cross-sectional view along line A-A′ of FIG. 1A. FIG. 2 is a schematic cross-sectional plan view along line B-B′ of FIG. 1B. In addition, the compound semiconductor light emitting diode 101 is shown as an example of an upper-lower electrode structure having electrodes in upper and lower faces of the light emitting diode device.

As shown in FIG. 1B, in the compound semiconductor light emitting diode 101, the device structure portion 10 is formed on a one surface 25a of the transparent base portion 25 made of an optically transparent material, and the first ohmic electrode 1 having one polarity is formed on a plane 10a of the front side of the device structure portion 10.

A mesa 90 having a trapezoidal cross-sectional shape including an upper bottom face 90a, a lower bottom face 90b, and an inclined side face 90d is formed on the opposite side to the one surface 25a of the transparent base portion 25 such that the lower bottom face 90b smaller than the upper bottom face 90a faces the opposite side to the front face.

Furthermore, a second ohmic electrode 5 having the other polarity is formed on the lower bottom face 90b of the mesa 90. Moreover, a metal coating film 6 is formed to cover the second ohmic electrode 5, the lower bottom face 90b, and the inclined side face 90d, and a metallic pedestal portion 7 is formed to cover the metal coating film 6.

Here, the direction indicated by the arrow f is a front direction, from which the compound semiconductor light emitting diode 101 radiates light.

First Ohmic Electrode

As shown in FIG. 1A, the first ohmic electrode 1 having one polarity is configured as a circular electrode on a plane 10a in the front direction f of the device structure portion 10, i.e., on a plane 11a in the front direction f of the contact layer 11. In addition, the one polarity may be either negative (−) or positive (+). The other polarity, which will be described below, is opposite to the one polarity. If the one polarity is positive (+), the other polarity is negative (−). If the one polarity is negative (−), the other polarity is positive (+).

The compound semiconductor layer 2 includes a device structure portion 10 and a growth base layer 3. The device structure portion 10 is configured by stacking a contact layer 11, a lower clad layer 12, a light emitting layer 13, and an upper clad layer 14.

Device Structure Portion

The device structure portion 10 shown in FIG. 1B includes a p-n junction double-hetero (DH) structure which is important and responsible for light emission. According to the present invention, the device structure portion 10 includes a first conductivity type contact layer 11, a first conductivity type lower clad layer 12, a light emitting layer 13 composed of (Al_{X}Ga_{1-X})_{0.5}In_{0.5}P (0≦X<1) having a first conductivity type or an opposite conductivity type to the first conductivity type, and an upper clad layer 14 having an opposite conductivity type to the first conductivity type.

If the first conductivity type is an n-type, the opposite conductivity type to the first conductivity type is a p-type. On the contrary, if the first conductivity type is a p-type, the opposite conductivity type to the first conductivity type is an n-type.

The device structure portion 10 is formed by preferably using a single crystal material as the device structure portion formation substrate and sequentially stacking, thereon, for example, an n-type contact layer 11 composed of (Al_{0.5}Ga_{0.5})_{0.5}In_{0.5}P, a lower clad layer 12 composed of (Al_{0.7}Ga_{0.3})_{0.5}In_{0.5}P, a light emitting layer 13 composed of undoped (Al_{0.2}Ga_{0.8})_{0.5}In_{0.5}P, and an upper clad layer 14 composed of p-type (Al_{0.7}Ga_{0.3})_{0.5}In_{0.5}P.

Each of the layers 11 to 14 may be formed through a growth means such as organic metal chemical vapor deposition (MOCVD) method or a molecular beam epitaxial (MBE) method, for example, by using III-V group semiconductor single crystals such as gallium arsenide (GaAs), indium phosphide (InP), or gallium phosphide (GaP) or single-element semiconductor single crystals such as silicon (Si) as the device structure portion formation substrate.

For example, when each of the layers 11 to 14 is stacked on a GaAs single crystal substrate having a plane inclined by 15° with respect to a (001) crystal face as a surface using a decompression type MOCVD method, the substrate temperature is preferably set to 710 to 750° C.

Contact Layer

For example, it is preferable that the carrier concentration of the n-type contact layer 11 is set to 1×10¹⁸ cm⁻³ to 3×10¹⁸ cm⁻³ and the thickness of the same layer 11 is set to 1 to 2 μm.

First Buffer Layer

In order to stack the contact layer 11, a first buffer layer may be formed on the device structure portion formation substrate, and then, the contact layer 11 may be formed on the buffer layer.

If the first buffer layer inserted between the device structure portion formation substrate and the contact layer 11 is an n-type, it is preferable that the carrier concentration thereof is set to 1×10¹⁸ cm⁻³ to 3×10¹⁸ cm⁻³ and the thickness of the layer is set to 0.1 to 0.3 μm. For example, the first buffer layer made of GaAs may be provided on a GaAs substrate, and the contact layer 11 may be formed thereon. In order to manufacture the compound semiconductor light emitting diode 101 according to the present invention, when the first ohmic electrode having one polarity provided in the device structure portion 10 is provided on the first buffer layer, it is necessary that the first buffer layer and the contact layer 11 have the same conductivity type.

Lower Clad Layer

For example, it is preferable that the carrier concentration of the n-type lower clad layer 12 is set to 7×10¹⁷ cm⁻³ to 9×10¹⁷ cm⁻³ and the thickness of the same layer 12 is set to 0.5 μm to 1.5 μm. The lower clad layer 12 is preferably made of a semiconductor material having a larger forbidden band width (band gap) and a larger refractive index than those of (Al_{X}Ga_{1-X})_{Y}In_{1-Y}P (0≦X≦1, 0<Y≦1) contained in the light emitting layer 13. For example, in the light emitting layer 13 composed of (Al_{0.4}Ga_{0.6})_{0.5}In_{0.5}P having a yellow-green color and a light-emitting peak wavelength of about 570 nm, the lower clad layer 12 may be composed of Al_{0.5}In_{0.5}P.

Light Emitting Layer

The light emitting layer 13 is made of mixed crystals of aluminum phosphide.gallium.indium (having a composition of (Al_{X}Ga_{1-X})_{0.5}In_{0.5}P; 0≦X<1) having either a first conductivity type or an opposite conductivity type to the first conductivity type.

It is preferable that the thickness of the light emitting layer 13 is set to 0.7 μm to 0.9 μm. In order to obtain monochromatically an excellent light emission, the light emitting layer 13 may have a single quantum well (SQW) structure or a multiple quantum well (MQW) structure. For example, a multiple quantum well (MQW) structure obtained by stacking 20 unitary stack bodies each of which includes a well layer composed of (Al_{0.2}Ga_{0.8})_{0.5}In_{0.5}P and a barrier layer composed of (Al_{0.7}Ga_{0.3})_{0.5}In_{0.5}P may be used. In the well layer or barrier layer composed of (Al_{X}Ga_{1-X})_{Y}In_{1-Y}P (0≦X≦1, 0<Y≦1) and included in the quantum well (QW) structure, the composition (X) of aluminum (Al) is appropriately determined such that a desired light emission wavelength can be obtained with a range of 0≦X≦1. When a GaAs single crystal is used in the substrate, the composition ratio of indium (In) (1−Y) is preferably set to 0.5 considering the lattice matching with GaAs.

Electric Current Diffusion Layer, Electric Current Blocking Layer, Intermediate Layer

An electric current diffusion layer made of a low resistance conductive material for diffusing a device operation electric current for operating the light emitting diode into the entire light emission layer 13 may be provided between the light emitting layer 13 and the lower clad layer 12.

In addition, an electric current blocking layer made of a high resistance or insulative material for intentionally limiting the area for flowing the device operation electric current of the light emitting diode may be provided in an appropriate place between the light emitting layer 13 and the lower clad layer 12.

Furthermore, an intermediate layer for alleviating discontinuity between both bands may be provided between the light emitting layer 13 and the lower clad layer 12 or between the light emitting layer 13 and the upper clad layer 14. It is preferable that the intermediate layer is made of a semiconductor material having a forbidden band width between that of a material of the light emitting layer 13 and that of a material of the clad layer 12 and 14.

Upper Clad Layer

It is preferable that the upper clad layer 14 is made of a semiconductor material having a larger forbidden band width and a larger refractive index than those of (Al_{X}Ga_{1-X})_{Y}In_{1-Y}P (0≦X≦1, 0<Y≦1) contained in the light emitting layer 13. For example, in the light emitting layer 13 composed of (Al_{0.4}Ga_{0.6})_{0.5}In_{0.5}P which has a light emission peak wavelength of about 570 nm and emits light of a yellow-green color, the upper clad layer 14 may be composed of Al_{0.5}In_{0.5}P. The upper clad layer 14 may be made of a semiconductor material having an opposite conductivity type to that of the lower clad layer 12. For example, it is preferable that the carrier concentration of the p-type upper clad layer 14 is set to 1×10¹⁸ cm⁻³ to 3×10¹⁸ cm⁻³ and the thickness of the same layer 11 is set to 1 μm to 2 μm.

Transparent Base Portion

A device structure portion 10 is formed on the one surface 25a of the transparent base portion 25. A mesa 90 is formed on the opposite side of the one surface 25a of the transparent base portion 25. The transparent base portion 25 includes the growth base layer 3 and the transparent bonding substrate 4 in the light emitting diode shown in FIGS. 1A and 1B. The transparent base portion 25 is made of a material capable of transmitting the light emitting from the device structure portion 10.

Growth Base Layer

The face 10b opposite to the front side of the device structure portion 10 is bonded to the one surface 25a of the transparent base portion 25 and adjoins the upper clad layer 14. In addition, as described below, since the one surface 25a of the transparent base portion 25 functions as a face for initiating growth of the growth base layer 3, it is called a growth initiation surface 3a.

The growth base layer 3 may be composed of aluminum arsenide.gallium (Al_{X}Ga_{1-X}As; 0<X≦1) or ((Al_{X}Ga_{1-X})_{Y}In_{1-Y}P; 0≦X≦1, 0<Y≦1) which provides a forbidden band width capable of sufficiently transmitting the light emission, for example, from the GaP layer or the device structure portion 10.

When the growth base layer 3 is made of a GaP layer grown through a MOCVD method, it is preferable that the thickness of the growth base layer 3 is equal to or larger than 5 μm and equal to or smaller than 20 μm, more preferably, equal to or larger than 8 μm and equal to or smaller than 10 μm in order to prevent considerable warping.

Since the compound semiconductor light emitting diode 101 according to the present invention has a structure that flows a device operation electric current via the internal side of the transparent base portion 25 as described below, it is preferable that the conductivity type of the growth base layer 3 is identical to that of the upper clad layer 14 adjoining the growth initiation surface 3a. In other words, if the upper clad layer 14 has a first conductivity type, the growth base layer 3 is also made of a material having the first conductivity type.

The growth base layer 3 may be grown through a growth means such as a MOCVD method or a liquid phase epitaxial (LPE) method. When the growth base layer 3 is made of a p-type GaP layer grown through a MOCVD method, the growth base layer 3 having a low resistance to the flow of the device operation electric current may be made from the p-type GaP layer having a carrier concentration of 2×10¹⁸ cm⁻³ to 4×10¹⁸ cm⁻³.

Second Buffer Layer, Bragg Reflection Layer

When the growth base layer 3 is provided on the upper clad layer 14, a second buffer layer for alleviating lattice mismatching between the growth base layer 3 and the upper clad layer 14 may be provided.

A Bragg reflection layer or the like having a function of reflecting the light emission from the device structure portion 10 to the external side of the light emitting diode may be inserted between the growth base layer 3 and the upper clad layer 14.

Transparent Bonding Substrate

The transparent base portion 25 includes a bonding member for bonding the transparent bonding substrate 4 to the face 3b opposite to the growth initiation surface 3a of the growth base layer 3 as illustrated in FIGS. 1A and 1B.

Since the compound semiconductor light emitting diode 101 according to the present invention has a structure of flowing the device operation electric current via the internal side of the transparent base portion 25 as described below, the transparent bonding substrate 4 bonded to the growth base layer 3 is made of a conductive material having a low resistance together with the growth base layer 3. Optically transparent but electrically insulative oxide materials such as glass or sapphire (α-Al₂O₃) are not proper for a material of the transparent bonding substrate 4.

For example, in a preferable transparent bonding substrate 4, a GaP single crystal of which a (111) or (100) crystal face is used as the face bonded to the growth base layer 3 may be used. Since the visible light beam absorption capability of the GaP crystal is low, it is appropriate to obtain a high luminance compound semiconductor visible light emitting diode. Particularly, since the n-type GaP crystal has a higher transmittance for the visible light beam in comparison with the p-type GaP crystal having the same impurity concentration, it is more appropriate for use as the transparent bonding substrate 4.

When the n-type GaP crystal is used as the transparent bonding substrate 4 in order to obtain the compound semiconductor light emitting diode 101 according to the present invention, it is necessary to also make the upper clad layer 14 and the growth base layer 3 have the same conductivity type, i.e., the n-type layer, in order to allow the device operation electric current to flow. In this configuration, if the growth base layer 3 is also made of the n-type GaP layer, a material having the same characteristics such as mechanical strength and a thermal expansion coefficient is bonded. Therefore, it is possible to configure the transparent base portion 25 strongly bonded with an excellent adhesion.

The thickness of the transparent bonding substrate 4 is preferably set to 10 μm to 300 μm, and more preferably, 100 μm to 150 μm. When the thickness is smaller than 10 μm, the mechanical strength for supporting the LED 101 becomes insufficient, and thus, it is not appropriate. Meanwhile, if the thickness is larger than 300 μm, it is necessary to insert a deep trench for the dicing. Therefore, it is difficult to carry out efficient slicing into separate compound semiconductor light emitting diodes 101.

When the transparent bonding substrate 4 is bonded to the growth base layer 3, if the bonding surfaces of both layers are mirror-polished, it is possible to bond them to each other with an excellent adhesion. For example, if the roughness of the bonding surface is set to 0.10 nm to 0.20 nm as a root-mean-square (rms) value, it is possible to achieve strong bonding. Specifically, the transparent base portion 25 is configured by bonding the surface of the growth base layer 3 mirror-polished to 0.17 nm to 0.19 nm as the root-mean-square value with the surface of the transparent bonding substrate 4 mirror-polished to 0.10 nm to 0.14 nm as the root-mean-square value.

Mesa

As shown in FIG. 1B, a mesa 90 of which the vertical cross-sectional shape is an inverted isosceles trapezoidal shape is provided on the opposite side of the one surface 25a of the transparent base portion 25. In addition, as shown in FIG. 2, the planary cross-sectional shape of the mesa 90 is an approximately rectangular shape. The mesa 90 includes a transparent bonding substrate 4 bonded to the growth base layer 3. Therefore, a thickness d of the mesa 90 is set to be equal to the thickness of the transparent bonding substrate 4.

In addition, the planary cross-sectional shape of the mesa 90 is not particularly limited, but may be circular or polygonal.

In order to obtain the compound semiconductor light emitting diode 101 according to the present invention, the inclination angle α of the inclined side face 90d forming the circumferential shape of the mesa 90 is preferably set to be equal to or larger than 10° and equal to or smaller than 45° with respect to a normal line v of the surface 25a of the transparent base portion 25. The mesa having the inclined side face 90d of such an angle can form a reflection mirror capable of effectively extracting the light emitted from the device structure portion 10 in a front direction f of the light emitting diode. When the inclination angle α is smaller than 10° or larger than 45° with respect to the normal line v, it is difficult to effectively reflect the light emitted from the device structure portion 10 in the front direction f.

The height d of the mesa 90 is preferably 10 μm to 300 μm, and more preferably, 100 μm to 150 μm.

Roughened Surface

If the inclined side face 90d of the mesa 90 is roughened, it is possible to form a reflection mirror appropriate to irregularly reflect the light incident from the device structure portion 10 to the inclined side face 90d of the mesa 90. As a result, due to the irregular reflection, it is possible to extract light in the front direction f of the compound semiconductor light emitting diode 101 and contribute to the high luminance of the compound semiconductor light emitting diode 101. The roughened surface may be formed through a treatment for forming unevenness having a height difference of 0.1 μm to 10 μm through a mechanical machining means such as a sand blast or a wet etching means using acid.

In addition, if the bottom face 90b of the mesa 90 as well as the inclined side face 90d of the mesa 90 is roughened through the aforementioned method or the like, and a reflection mirror is formed based on such a roughened surface, it is possible to increase the intensity of the reflection light in the front direction f of the compound semiconductor light emitting diode 101. Therefore, it is possible to contribute to the high luminance of the compound semiconductor light emitting diode 101.

Method of Forming Mesa

The mesa 90 may be formed on the transparent base portion 25 through a dicing method, a wet etching method, a dry etching method, a scribe method, or a laser machining method, or any combination thereof.

For example, through a dicing method, a trench is formed across the length and the breadth of the transparent base portion 25 by cutting the surface of the transparent base portion 25 toward the internal side of the transparent base portion 25 using a cutting blade having a shearing edge of which the cross-sectional shape is an isosceles trapezoid shape. The cross-sectional shape of the trench is approximately identical to the cross-sectional shape of the shearing edge. When the aforementioned blade is used, the resultant cross-sectional shape of the trench becomes an isosceles trapezoidal shape. As a result, in the areas other than the trench, the mesa 90 having an isosceles trapezoidal cross-sectional shape remains.

Second Ohmic Electrode

As shown in FIG. 2, the second ohmic electrode 5 includes a plurality of circular electrodes arranged symmetrically with respect to the center of the lower bottom face 90b of the mesa 90 having an approximately rectangular shape.

On the lower bottom face 90b of the mesa 90, the second ohmic electrode 5 having a polarity corresponding to the conductivity type of the transparent bonding substrate 4 or the growth base layer 3 of the transparent base portion 25 is arranged.

The second ohmic electrode 5 of the n-type may include, for example, a gold-germanium (Au—Ge) alloy. In addition, the side making contact with the n-type semiconductor layer may be made of a metal electrode having a multi-layer structure including an Au—Ge alloy film. For example, the second ohmic electrode 5 may be made of a three-layered structure including an Au—Ge alloy, a nickel (Ni) film, and a gold (Au) film.

The second ohmic electrode 5 need not necessarily be made of a single electrode in a numerical sense, but may be obtained by arranging a plurality of electrodes on the lower bottom face 90b of the mesa 90. By arranging a plurality of second ohmic electrodes 5 on the lower bottom face 90b of the mesa 90, it is possible to uniformly diffuse the device operation electric current inside the transparent base portion 25.

When a plurality of second ohmic electrodes 5 is provided on the lower bottom face 90b of a single mesa 90, they may not necessarily have the same planary shape. Preferably, it has a shape capable of diffusing the device operation electric current across a wide area of the transparent base portion 25.

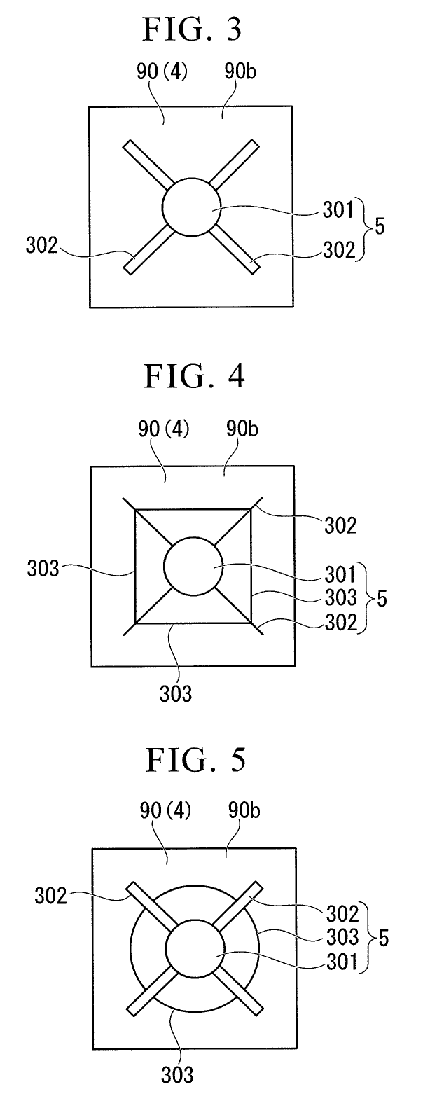

FIGS. 3 to 11 are schematic diagrams illustrating another exemplary arrangement of the second ohmic electrode 5 formed on the lower bottom face 90b of the mesa 90 formed in an approximately rectangular shape. In this arrangement, it is possible to diffuse the device operation electric current across a wide area of the transparent base portion 25 and uniformly flow the device operation electric current across the transparent base portion 25.

For example, the second ohmic electrode 5 shown in FIG. 3 includes a main electrode 301 having a circular shape arranged in the center of the lower bottom face 90b of the mesa 90 and two linear electrodes 302 electrically connected to the main electrode 301 and arranged perpendicular to each other.

The second ohmic electrode 5 shown in FIG. 4 includes a rectangular frame electrode 303 surrounding the main electrode 301 in addition to the linear electrode 302 and the main electrode 301 included in the second ohmic electrode 5 shown in FIG. 2.

The second ohmic electrode 5 shown in FIG. 5 includes a circular frame electrode 303 surrounding the main electrode 301 in addition to the linear electrode 302 and the main electrode 301 included in the second ohmic electrode 5 shown in FIG. 2.

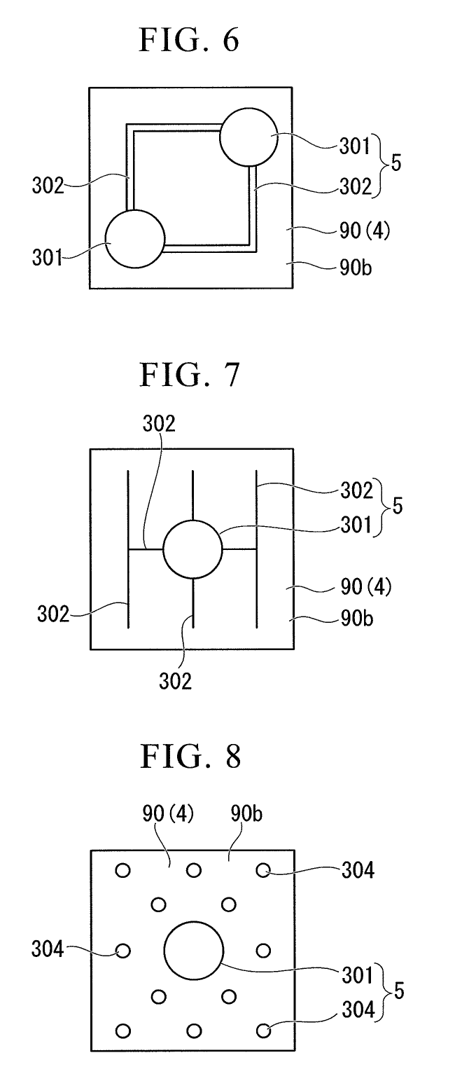

The second ohmic electrode 5 shown in FIG. 6 includes two main electrodes 301 having a circular shape arranged opposite to the lower bottom face 90b of the mesa 90 and a linear electrode 302 arranged in a rectangular shape and electrically connected to the two circular electrodes 301. In addition, the arrangement of the linear electrode 302 is not limited to the rectangular shape, but may have a circular shape.

In addition, the second ohmic electrode 5 shown in FIG. 7 includes a circular main electrode 301 arranged in the center of the lower bottom face 90b of the mesa 90 and four linear electrodes 302. The four linear electrodes 302 include three linear electrodes 302 arranged approximately in parallel and a single linear electrode 302 perpendicular to the three linear electrodes 302. At the circular electrode 301, two linear electrodes 302 perpendicularly intersect with each other.

The second ohmic electrode 5 shown in FIG. 8 includes a circular main electrode 301 arranged in the center and circular subsidiary electrodes 304 that are formed around the main electrode 301 and smaller than the main electrode 301. The subsidiary electrodes 304 are also ohmic electrodes. The subsidiary electrodes 304 are symmetrically arranged with respect to the center.

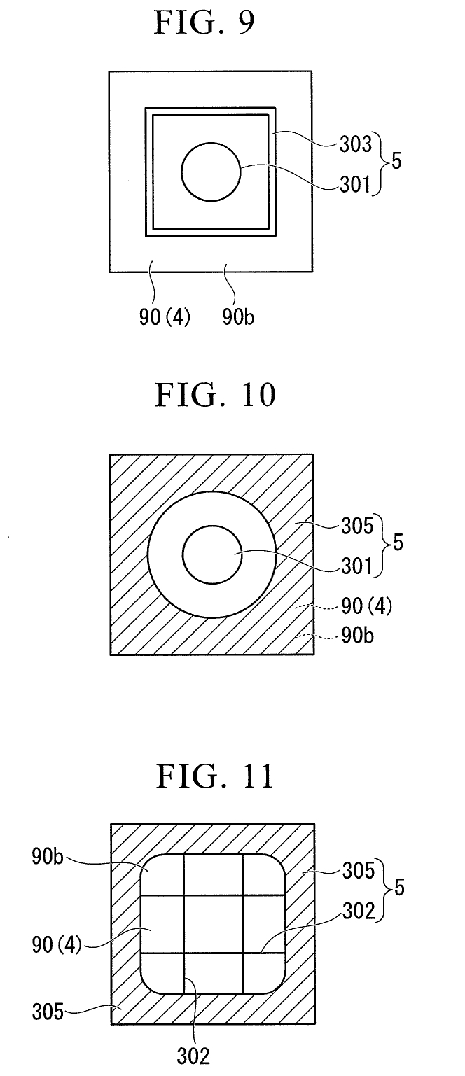

The second ohmic electrode 5 shown in FIG. 9 includes a circular main electrode 301 arranged in the center and a rectangular frame electrode 303 surrounding the main electrode 301.

The second ohmic electrode 5 shown in FIG. 10 includes a circular electrode 301 arranged in the center of the lower bottom face 90b of the meas 90 and an outer frame electrode 305 equally spaced from the outer periphery of the electrode 301.

The second ohmic electrode 5 shown in FIG. 11 includes an outer frame electrode 305 obtained by hollowing out the center of the lower bottom face 90b of the mesa 90 in approximately a rectangular shape and four linear electrodes 302 arranged across the length and breadth of the hollowed portion.

In the second ohmic electrode 5 shown in FIGS. 3 to 11, the shapes of the main electrode 301 and the subsidiary electrode 304 are not limited to the circular shape, but may have other shapes. In addition, the planary shape of the frame electrode 303 is not limited to the rectangular or circular shape, but may have other shapes. Furthermore, the number of frame electrodes 303 is not limited particularly, but may be plural. Moreover, the shape of the outer frame electrode 305 is not also particularly limited.

Any one of the second ohmic electrodes 5 shown in FIGS. 3 to 11 is not a solid electrode which covers the entire surface of the lower bottom face 90b of the mesa 90. Therefore, the remaining portion except for the second ohmic electrode 5 is the exposed portion of the lower bottom face 90b of the mesa 90.

For example, in the second ohmic electrode 5 shown in FIG. 3, the remaining portion except for the main electrode 301 and the two linear electrodes 302 is the exposed portion of the lower bottom face 90b of the mesa 90. In addition, in the second ohmic electrode 5 shown in FIG. 8, the remaining portion except for the main electrode 301 and a plurality of subsidiary electrodes 304 is the exposed portion of the lower bottom face 90b of the mesa 90.

The lower bottom face 90b of the mesa 90 is covered by a metal coating film together with the inclined side face 90d of the mesa 90 as described below. Such a metal coating film reflects the light incident on the mesa 90. Since a shape that can advantageously diffuse the device operation electric current across the transparent base portion 25 is provided, if the surface of the mesa is exposed, the light transmitting the lower bottom face 90b of the mesa 90 can be reflected to the front direction f of the compound semiconductor light emitting diode 101 by means of the reflection mirror made of such a metal coating film. Therefore, it is possible to increase the amount of light reflected to the front direction f and contribute to the high luminance of the compound semiconductor visible light emitting diode 101.

Metal Coating Film

As shown in FIG. 1B, the metal coating film 6 is formed to cover the second ohmic electrode 5, the lower bottom face 90b, and inclined side face 90d. The metal coating film 6 is formed to cover the opposite side of the one surface 25a of the transparent base portion 25 and cover a part of the growth base layer 3 as well as the mesa 90.

In addition, a metallic pedestal portion 7 is formed to cover the metal coating film 6.

The lower bottom face 90b and the inclined side face 90d of the mesa 90 are provided with the metal coating film 6 for covering those surfaces. This metal coating film 6 is preferably made of a metallic material capable of making cohesive contact with the transparent bonding substrate 4 or the growth base layer 3 of the transparent base portion 25 of the mesa 90 in order to prevent exfoliation between the pedestal portion 7 and the transparent base portion 25 described below and surely fix the compound semiconductor light emitting diode 101 in the pedestal portion 7.

In addition, the metal coating film 6 is also preferably made of a metallic material capable of strongly adhering to the metallic material of the second ohmic electrode 5 of the lower bottom face 90b of the mesa 90 in order to prevent a conduction resistance caused by exfoliation between the second ohmic electrode 5 and the metal coating film 6 due to adhesion failure from increasing and provide the device operation electric current from the pedestal portion 7 to the second ohmic electrode 5.

If the metal coating film 6 is formed of a material having a higher reflectance, for example, equal to or higher than 80%, than that of the metallic material of the second ohmic electrode 5 for the visible light beam emitted from the device structure portion 10, it can be effectively used as a reflection mirror for reflecting the emitted light.

Particularly, if it is made of a metallic material containing silver (Ag), aluminum (Al), or platinum (Pt), it is possible to obtain a compound semiconductor light emitting diode 101 representing an orientation characteristic having a maximum intensity in the front direction f by reflecting the light emitted from the device structure portion 10 to the front direction f.

A material of the metal film 6 may include a single material selected from any one of silver (Ag), aluminum (Al), or platinum (Pt), or an alloy containing any one of these.

Pedestal Portion

As shown in FIG. 1B, a metallic pedestal portion 7 is formed to cover the metal coating film 6.

Specifically, the pedestal portion 7 is provided to cover the lower bottom face 90b and the inclined side face 90d of the mesa 90 through the metal coating film 6.

By allowing the pedestal portion 7 to mechanically strongly support the compound semiconductor light emitting diode 101 as described above, it is possible to improve the mechanical stability of the compound semiconductor light emitting diode 101.

The pedestal portion 7 is provided to cover the inclined side face 90d and the lower bottom face 90b of the mesa 90 and the circumference of the mesa 90 in the lower portion of the compound semiconductor light emitting diode 101 through the metal coating film 6. The pedestal portion 7 mechanically strongly supports the compound semiconductor light emitting diode 101 and discharges the heat generated during operation to the outer side. In order to effectively discharge the generated heat, the pedestal portion 7 is preferably made of a material having a thermal conductivity equal to or higher than 100 W/mK, and more preferably, equal to or higher than 200 W/mK. For example, a metallic material containing any one of copper (Cu), aluminum (Al), gold (Au), or platinum (Pt) may be preferably used to configure the pedestal portion 7.

The pedestal portion 7 may be made of a single material selected from any one of copper (Cu), aluminum (Al), gold (Au), or platinum (Pt) or a metallic material containing at least one of them.

Since the second ohmic electrode 5 is connected to the pedestal portion 7 through the metal coating film 6, the pedestal portion 7 may be used as a terminal. In addition, it is unnecessary to perform wire bonding for a p-type terminal which would be formed during manufacturing a light emitting diode lamp having a single-sided electrode structure. Therefore, it is possible to simplify the process of manufacturing the light emitting diode lamp.

Since the compound semiconductor light emitting diode 101 according to an embodiment of the present invention has a double-sided electrode structure in which the first ohmic electrode 1 and the second ohmic electrode 5 are arranged in upper and lower portions, it is possible to increase the area of the light emitting layer 13. At the same time, since the second ohmic electrode 5 obstructing effective light output is not formed in the front direction f (the light output side), it is possible to improve the luminance of the light emitted from the compound semiconductor light emitting diode 101.

Since the compound semiconductor light emitting diode 101 according to an embodiment of the present invention includes a metallic pedestal portion 7 that is electrically connected to the second ohmic electrode 5 through the metal coating film 6, and the second ohmic electrode 5 is connected to the metallic pedestal portion 7 through the metal coating film 6, it is not necessary to perform wire bonding for the p-type terminal when manufacturing the light emitting diode lamp, and it is possible to simplify the manufacturing process.

Since the compound semiconductor light emitting diode 101 according to an embodiment of the present invention includes a mesa 90, of which the vertical cross-sectional shape is an inverted isosceles trapezoidal shape, on the opposite side to the surface 25a of the transparent base portion 25, it is possible to effectively reflect the light from the light emitting layer 13 to the front direction f of the mesa 90 and thus, improve the luminance of the light emitted from the compound semiconductor light emitting diode 101.

Since the compound semiconductor light emitting diode 101 according to an embodiment of the present invention has a configuration in that the metal coating film 6 covers the second ohmic electrode 5, the lower bottom face 90b, and the inclined side face 90d, it is possible to effectively reflect the light from the light emitting layer 13 to the front direction f of the metal coating film 6 and thus, improve the luminance of the light emitted from the compound semiconductor light emitting diode 101.

Since the compound semiconductor light emitting diode 101 according to an embodiment of the present invention includes a metallic pedestal portion 7, it is possible to increase the mechanical strength of the compound semiconductor light emitting diode 101 and, at the same time, improve the heat dissipation capability and the product lifetime.

In the compound semiconductor light emitting diode 101 according to an embodiment of the present invention, since the transparent base portion 25 includes a growth base layer 3, it is possible to form the transparent base portion 25 as a layer having a high transparency and a high carrier conductivity and improve the luminance of the light emitted from the compound semiconductor light emitting diode 101. In addition, it is possible to simplify the manufacturing process and improve productivity.

In the compound semiconductor light emitting diode 101 according to an embodiment of the present invention, since the transparent base portion 25 includes the growth base layer 3 and the transparent bonding substrate 4 bonded to the growth base layer 3, it is possible to form the transparent base portion 25 as a layer having a high transparency and a high carrier conductivity and improve the luminance of the light emitted from the compound semiconductor light emitting diode 101.

In the compound semiconductor light emitting diode 101 according to an embodiment of the present invention, since the transparent bonding substrate 4 has the same conductivity type as that of the growth base layer 3, the light emitting diode has upper and lower electrode structure. Therefore, it is possible to effectively flow the device operation electric current and improve the light emission efficiency of the compound semiconductor light emitting diode 101.

In the compound semiconductor light emitting diode 101 according to an embodiment of the present invention, since the face of the transparent bonding substrate 4 bonded to the growth base layer 3 is a mirror-polished surface having a roughness of 0.10 nm to 0.20 nm as a root-mean-square value, it is possible to improve adhesion between the transparent bonding substrate 4 and the growth base layer 3, and the product lifetime.

In the compound semiconductor light emitting diode 101 according to an embodiment of the present invention, since the inclination angle α of the inclined side face 90d is equal to or larger than 10° and equal to or smaller than 45° with respect to the normal line v of the surface 25a of the transparent base portion 25, it is possible to effectively reflect the light into the front direction f and improve the light emission efficiency of the compound semiconductor light emitting diode 101.

In the compound semiconductor light emitting diode 101 according to an embodiment of the present invention, since the inclined side face 90d has a roughened surface having unevenness of a height difference equal to or larger than 0.1 μm and equal to or smaller than 10 μm, the light is irregularly reflected at the roughened surface and effectively reflected into the front direction f. Therefore, it is possible to improve the light emission efficiency of the compound semiconductor light emitting diode 101.

In the compound semiconductor light emitting diode 101 according to an embodiment of the present invention, since the lower bottom face 90b has a roughened surface having unevenness of a height difference equal to or larger than 0.1 μm and equal to or smaller than 10 μm, the light is irregularly reflected at the roughened surface and effectively reflected into the front direction f. Therefore, it is possible to improve the light emission efficiency of the compound semiconductor light emitting diode 101.

In the compound semiconductor light emitting diode 101 according to an embodiment of the present invention, since a plurality of the second ohmic electrodes 5 is arranged on the lower bottom face 90b, it is possible to obtain planary regularity of the device operation electric current flowing from the mesa 90 to the device structure portion 10. Therefore, it is possible to regulate the light emission intensity across the light output surface of the compound semiconductor light emitting diode 101.

In the compound semiconductor light emitting diode 101 according to an embodiment of the present invention, since the metal coating film 6 is made of a material different from that of the second ohmic electrode 5, the second ohmic electrode 5 can be made using a material capable of effectively injecting the electric current, and the metal coating film 6 can be made using a material capable of effectively reflecting light. Therefore, it is possible to improve the light emission efficiency of the compound semiconductor light emitting diode 101.

In the compound semiconductor light emitting diode 101 according to an embodiment of the present invention, since the metal coating film 6 is made of a material having a reflectance equal to or higher than 80% with respect to the light radiated from the device structure portion 10 and containing any one of silver, aluminum, or platinum, it is possible to improve the light emission efficiency of the compound semiconductor light emitting diode 101 by effectively reflecting the light radiated from the device structure portion 10 into the front direction f.

In the compound semiconductor light emitting diode 101 according to an embodiment of the present invention, since the metal coating film 6 is configured to cover the opposite side to the surface 25a of the transparent base portion 25, it is possible to improve the light emission efficiency of the compound semiconductor light emitting diode 101 by effectively reflecting the light radiated from the device structure portion 10 into the front direction f without loss.

In the compound semiconductor light emitting diode 101 according to an embodiment of the present invention, since the pedestal portion is made of a material having a thermal conductivity equal to or higher than 200 W/mK and containing any one of copper, aluminum, gold, or platinum, it is possible to improve the product lifetime by effectively radiating the heat generated during the light emission.

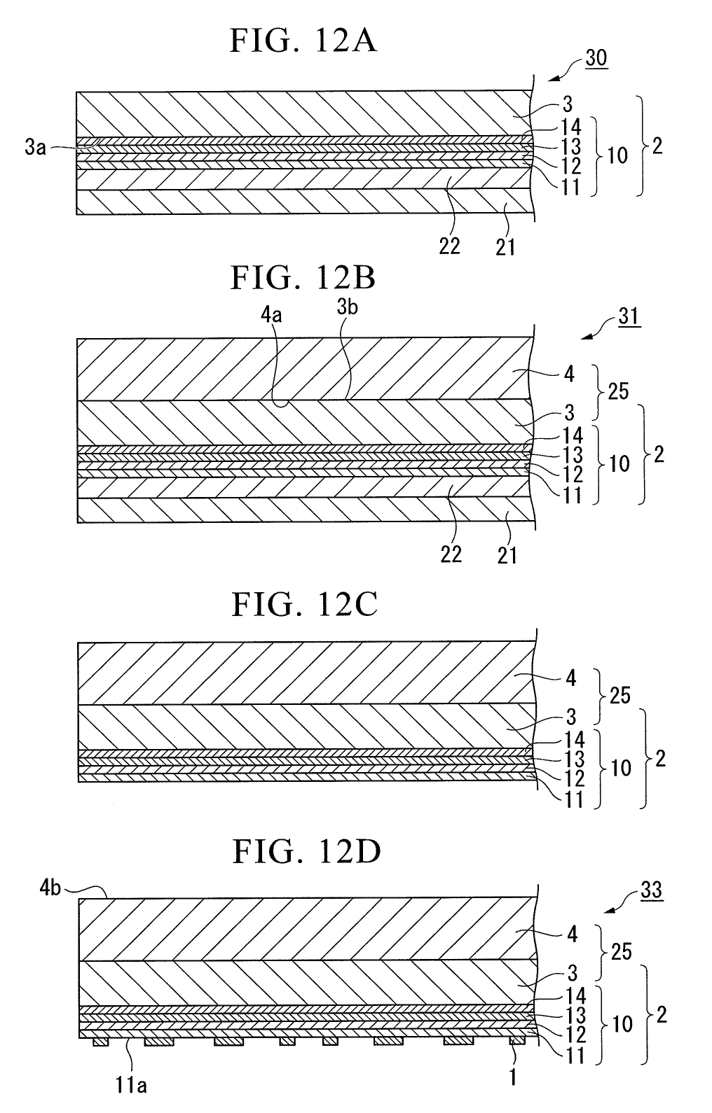

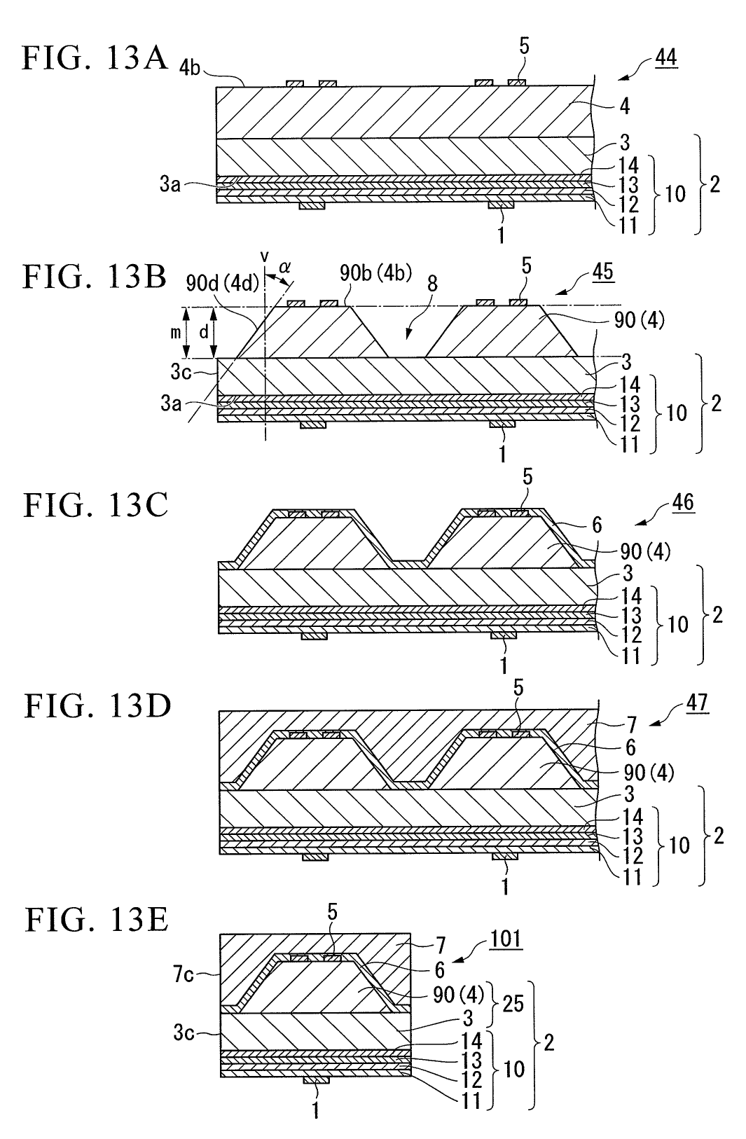

FIGS. 12A to 12D and 13A to 13E are manufacturing process diagrams illustrating an exemplary method of manufacturing a compound semiconductor light emitting diode 101, which will be described by assuming that the first ohmic electrode is an n-type.

The manufacturing process includes a process of forming the compound semiconductor layer formation, a process of bonding the transparent bonding substrate, a process of removing the GaAs substrate and the buffer layer, a process of forming the n-type ohmic electrode, a process of forming the p-type ohmic electrode, a process of forming the trench, a roughening process, a process of forming the metal coating film, a process of forming the pedestal portion, and a dicing process.

Hereinafter, each of the processes will be described.

Process of Forming Compound Semiconductor Layer

First, as a device structure portion formation substrate, a semiconductor substrate 21 made of GaAs single crystals having an inclination angle of 15° with respect to the (100) plane of an Si-doped n-type semiconductor is prepared.

The semiconductor substrate 21 is introduced into the decompression device, and the epitaxial wafer 30 shown in FIG. 12A is formed by sequentially stacking a first buffer layer 22 made of Si-doped n-type GaAs, a contact layer 11 made of Si-doped n-type (Al_{0.5}Ga_{0.5})_{0.5}In_{0.5}P, a lower clad layer 12 made of Si-doped n-type (Al_{0.7}Ga_{0.3})_{0.5}In_{0.5}P, a light emitting layer 13 made of 20 pairs of undoped (Al_{0.2}Ga_{0.8})_{0.5}In_{0.5}P/(Al_{0.7}Ga_{0.5})_{0.5}In_{0.5}P, an upper clad layer 14 made of Mg-doped p-type (Al_{0.7}Ga_{0.4})_{0.5}In_{0.5}P, and a p-type growth base layer 3 made of an Mg-doped p-type GaP layer using a MOCVD method.

In addition, a layer including the contact layer 11, the lower clad layer 12, the light emitting layer 13, and the upper clad layer 14 is called a device structure portion 10, and a stack structure including the device structure portion 10 and the p-type growth base layer 3 made of a p-type GaP layer is called a compound semiconductor layer 2.

The face of the p-type growth base layer 3 adjoining the upper clad layer 14 is the growth initiation surface 3a.

Each of the first buffer layer 22 and the compound semiconductor layer 2 contains trimethyl aluminum ((CH₃)₃Al), trimethyl gallium ((CH₃)₃Ga), and trimethyl indium ((CH₃)₃In) as materials of the III-group element.

Bis(cyclopentadiethyl)magnesium (bis-(C₅H₅)₂Mg) is used as a doping material of Mg, and disilane (Si₂H₆) is used as a doping material of Si.

In addition, phosphine (PH₃) or arsine (AsH₃) is used as a material of the V-group element.

The p-type growth base layer 3 made of a p-type GaP layer is grown at a substrate temperature of 730 to 770° C., and the first buffer layer 22, the contact layer 11, the lower clad layer 12, the light emitting layer 13, and the upper clad layer 14 are grown at a substrate temperature of 710 to 750° C.

The first buffer layer 22 has a carrier concentration of 1×10¹⁸ cm⁻³ to 3×10¹⁸ cm⁻³ and a thickness of 0.1 to 0.3 μm. The contact layer 11 is made of (Al_{0.5}Ga_{0.5})_{0.5}In_{0.5}P and has a carrier concentration of 1×10¹⁸ cm⁻³ to 3×10¹⁸ cm⁻³ and a thickness of approximately 1 to 2 μm. The lower clad layer 12 has a carrier concentration of 7×10¹⁷ cm⁻³ to 9×10¹⁷ cm⁻³ and a thickness of 0.5 to 1.5 μm. The light emitting layer 13 has a thickness of 0.7 to 0.9 μm in an undoped state. The upper clad layer 14 has a carrier concentration of 1×10¹⁷ cm⁻³ to 3×10¹⁷ cm⁻³ and a thickness of 0.5 to 1.5 μm. The p-type growth base layer 3 made of a p-type GaP layer has a carrier concentration of 2×10¹⁸ cm⁻³ to 4×10¹⁸ cm⁻³ and a thickness of 8 to 10 μm.

The p-type growth base layer 3 made of a p-type GaP layer is obtained by mirror-polishing the area up to a thickness of 0.5 to 1.5 μm from the surface. Through the mirror-polishing, the surface of the p-type growth base layer 3 made of the p-type GaP layer has a roughness of 0.17 to 0.19 nm.

Process of Bonding Transparent Bonding Substrate

First, the other face 3b of the p-type growth base layer 3 made of a p-type GaP layer is mirror-polished. Then, a transparent bonding substrate 4 bonded to this face 3b is prepared. Si is added to the transparent bonding substrate 4 so as to have a carrier concentration of 1×10¹⁷ cm⁻³ to 3×10¹⁷ cm⁻³, using a GaP single crystal having a plane orientation of (111). The transparent bonding substrate 4 has a diameter of 40 to 60 mm and a thickness of 200 to 300 μm. The surface of this transparent bonding substrate 4 is mirror-polished before it is bonded to the p-type growth base layer 3 made of a p-type GaP layer to have a roughness of 0.10 to 0.14 nm as a root-mean-square (rms) value.

The transparent bonding substrate 4 and the epitaxial wafer 30 are introduced into the decompression device, and evacuation is performed up to 2×10⁻⁵ Pa to 4×10⁻⁵ Pa in a decompressed state. Here, an accelerated Ar beam is irradiated on a bonding surface 4a of the transparent bonding substrate 4 and the other surface 3b of the p-type growth base layer 3 made of a p-type GaP layer of the epitaxial wafer 30 to remove pollution. Then, both surfaces are bonded at room temperature using a room temperature activated bonding method so that the bonding substrate 31 is manufactured as shown in FIG. 12B.

Process of Removing GaAs Substrate and Buffer Layer

Then, as shown in FIG. 12C, the GaAs substrate 21 and the first buffer layer 22 are selectively removed from the bonding substrate 31 ammonia-based etchant.

Process of Forming n-type Ohmic Electrode

Further, as shown in FIG. 12D, the n-type ohmic electrode 1 is formed on the surface 11a of the contact layer 11 so that the n-type ohmic electrode formation substrate 33 is formed.

The n-type ohmic electrode 1 is obtained by sequentially stacking AuGe (Ge mass %=12%) having a thickness of 0.1 to 0.2 μm, Ni having a thickness of 0.04 to 0.06 μm, and Au having a thickness of 0.8 to 1.2 μm using a vacuum deposition method.

Process of Forming p-type Ohmic Electrode

Next, in an n-type ohmic electrode formation substrate 33, AuBe having a thickness of 0.1 to 0.3 μm and Au having a thickness of 0.8 to 1.2 μm are sequentially stacked on the lower bottom face 4b of the transparent bonding substrate 4 using a vacuum deposition method so that the p-type ohmic electrode 5 is formed as shown in FIG. 13A.

Then, a heat treatment is performed for 5 to 15 minutes at a temperature of 400 to 500° C. so that both electrodes are alloyed. Through the alloying process, both electrodes can be made to have a low resistance.

Process of Forming Trenches

Next, as shown in FIG. 13B, trenches 8 are formed on the transparent bonding substrate 4 by routing trenches on the bottom face 4b of the transparent bonding substrate 4 using a dicing saw so that a trench formation substrate 45 is obtained.

In addition, by providing the trenches 8, the transparent bonding substrate 4 has an inclined side face 4d having an inclination angle α with respect to the normal line v of the growth initiation surface 3a of the growth base layer 3 so that the cross-sectional shape of the mesa 90 has an isosceles trapezoidal shape. Furthermore, a thickness m of the transparent bonding substrate 4 is equal to the thickness d of the mesa 90.

Roughening Process

The lower bottom face 4b and the inclined side face 4d of the transparent bonding substrate 4 are roughened by an adidic treatment. Other typical roughening processes may be employed.

Process of Forming Metal Coating Film

As shown in FIG. 13C, the trench formation substrate 45 is introduced into the decompression device, and a metal coating film 6 is formed by depositing Al having a thickness of 0.2 μm on the inclined side face 4d and the lower bottom face 4b of the transparent bonding substrate 4 using a vacuum deposition method so that a metal coating film formation substrate 46 is formed.

Process of Forming Pedestal portion

As shown in FIG. 13D, the metal coating film formation substrate 46 is extracted from the decompression device, and then, a copper plating is performed on the surface where the metal coating film 6 of the metal coating film formation substrate 46 is formed so that a pedestal portion formation substrate 47 is provided.

As a finishing plating, a precious metal plating or a soldering plating may be employed.

Dicing Process

Next, from the face where the pedestal portion 7 is formed, the pedestal portion formation substrate 47 is cut to make chips by dicing it perpendicularly to the growth initiation surface 3a at a constant interval (for example, at an interval of 1 mm) using a dicing saw so that the compound semiconductor light emitting diode 101 shown in FIG. 13E can be manufactured. The pollution and fractured layers caused by the dicing are etched out.

### Second Embodiment

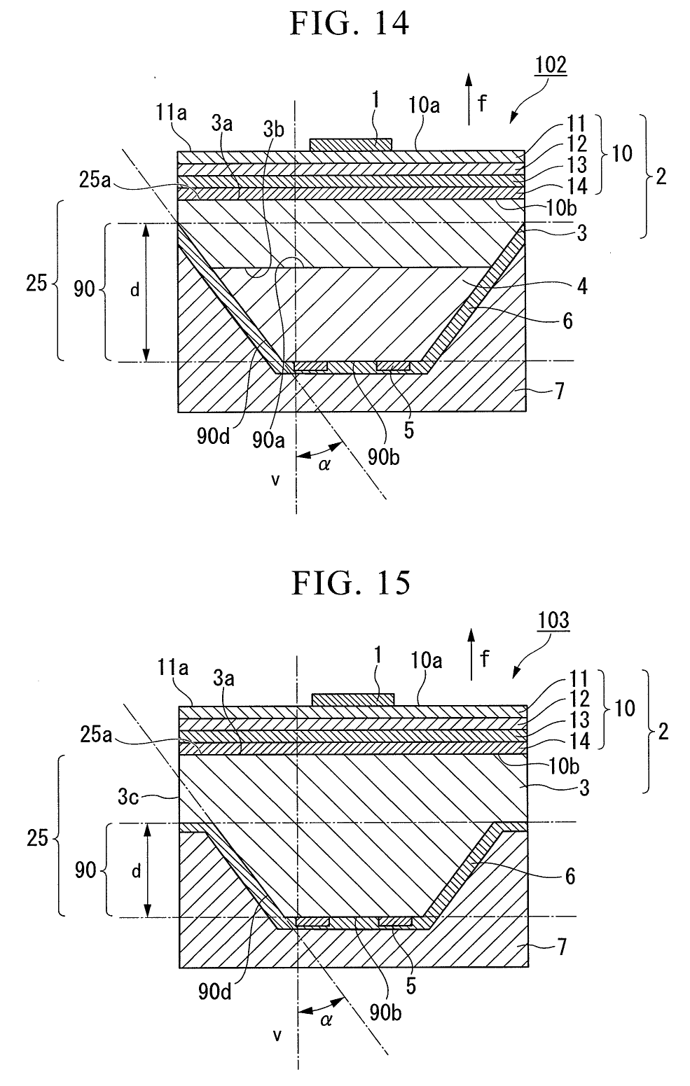

FIG. 14 is a schematic cross-sectional view illustrating an exemplary compound semiconductor light emitting diode according to another embodiment of the present invention.

A compound semiconductor light emitting diode 102 according to this embodiment of the present invention is similar to that of the first embodiment except that the mesa 90 is formed by notching a part of the transparent growth layer 3 when the mesa 90 is formed. In addition, like reference numerals denote like elements as in the first embodiment.

In this manner, the mesa 90 may be formed to size up from the transparent bonding substrate 4 to the growth base layer 3. When such a high mesa 90 is formed, the surface area of the inclined side face 90d of the mesa 90 increases.

If the inclined side face 90d having a larger surface area is covered by a metallic material having a high reflectance for the visible light, it is possible to form a reflection mirror having a larger surface area and obtain a high luminance compound semiconductor visible light emitting diode 102 having a high light extraction efficiency.

In the compound semiconductor light emitting diode 102 according to an embodiment of the present invention, since the mesa 90 is formed by notching a part of the transparent growth layer 3, it is possible to increase the area of the inclined side face 90d and improve the reflection rate to the front direction f from the inclined side face 90d. Therefore, it is possible to improve the luminance in the front direction f.

### Third Embodiment

FIG. 15 is a schematic cross-sectional view illustrating an exemplary compound semiconductor light emitting diode according to still another embodiment of the present invention.

A compound semiconductor light emitting diode 103 according to this embodiment of the present invention is similar to that of the first embodiment except that the transparent base portion 25 includes only the transparent growth layer 3. In addition, like reference numerals denote like elements as in the first embodiment.

In the compound semiconductor light emitting diode 103 according to an embodiment of the present invention, the transparent base portion 25 is made of the growth base layer 3 grown on the face 10b opposite to the front face of the device structure portion 10.

By providing such a configuration, it is possible to omit the process of bonding the transparent bonding substrate 4 and simplify the manufacturing process.

### Fourth Embodiment

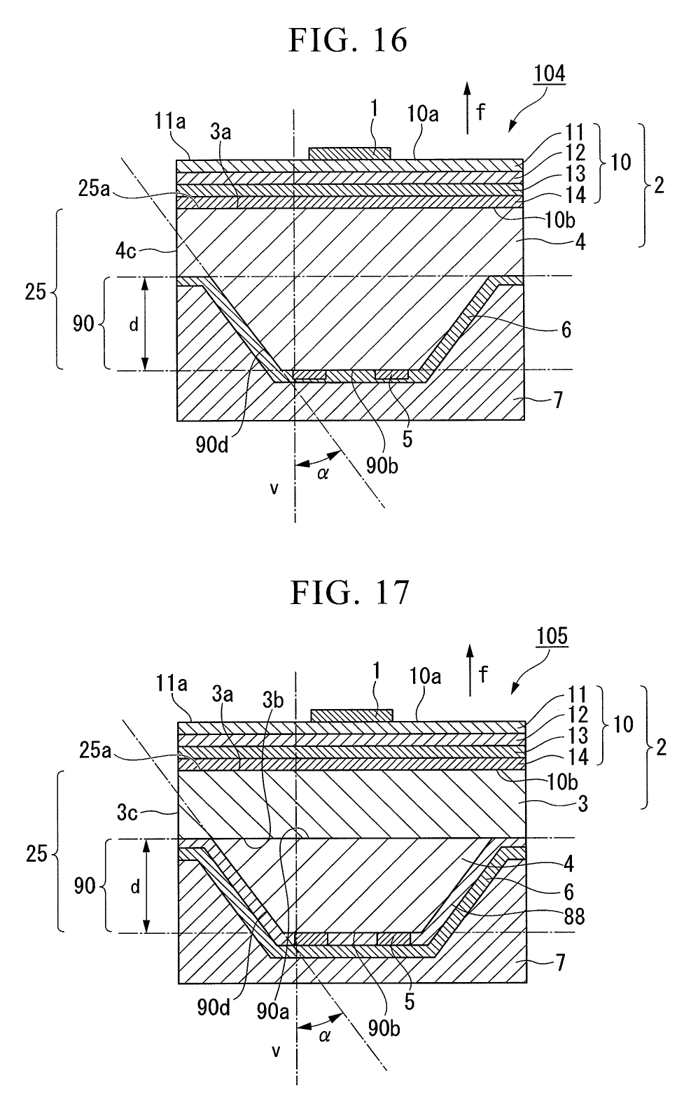

FIG. 16 is a schematic cross-sectional view illustrating an exemplary compound semiconductor light emitting diode according to further another embodiment of the present invention.

A compound semiconductor light emitting diode 104 according to this embodiment of the present invention is similar to that of the first embodiment except that the transparent base portion 25 includes only the transparent bonding substrate 4. In addition, like reference numerals denote like elements as in the first embodiment.

In this manner, the transparent base portion 25 may be made of the transparent bonding substrate 4 directly bonded to the upper clad layer 14. The transparent bonding substrate 4 directly bonded to the upper clad layer 14 can also transmit the light emitted from the device structure portion 10 such as GaP and can be made of a material having conductivity. The transparent bonding substrate 4 directly bonded to the upper clad layer 14 preferably has a thickness equal to or larger than 10 μm and equal to or smaller than 300 μm.

When the transparent bonding substrate 4 is bonded to the upper clad layer 14, if the bonding surfaces of both layers are mirror-polished, it is possible to bond both with excellent adhesion. For example, it is possible to provide a strong bonding if the bonding surfaces have a roughness of 0.10 nm to 0.20 nm as a root-means-square (rms) value.

In the compound semiconductor light emitting diode 104 according to this embodiment of the present invention, since the transparent base portion 25 includes the transparent bonding substrate 4, it is possible to omit the process of forming the growth base layer 3 and simplify the manufacturing process.

### Fifth Embodiment

FIG. 17 is a schematic cross-sectional view illustrating an exemplary compound semiconductor light emitting diode according to still further another embodiment of the present invention.

A compound semiconductor light emitting diode 105 according to this embodiment of the present invention is similar to that of the first embodiment except that a transparent oxide layer 88 is formed between the metal coating film 6 and the transparent base portion 25. In addition, like reference numerals denote like elements as in the first embodiment.

In addition, the transparent oxide layer 88 is not formed on the second ohmic electrode 5, and the second ohmic electrode 5 adjoins the metal coating film 6. The transparent oxide layer 88 on the second ohmic electrode 5 may be removed using a photolithography method.

By forming the transparent oxide layer 88 between the metal coating film 6 and the transparent base portion 25, it is possible to suppress reaction such as heat or light that may be generated between the metal coating film 6 and the transparent base portion 25 and maintain the reflectance of the metal coating film 6. Therefore, it is possible to maintain the luminance of the compound semiconductor light emitting diode 105.

The transparent oxide layer 88 is preferably conductive. By using the conductive transparent oxide layer 88, it is possible to remove the necessity of removing the transparent oxide layer 88 on the second ohmic electrode 5 using photolithography and thus it is possible to simplify the manufacturing process.

In the compound semiconductor light emitting diode 105 according to an embodiment of the present invention, since the transparent oxide layer 88 is inserted between the metal coating film 6 and the transparent base portion 25, it is possible to prevent degradation of the reflectance caused by reaction between the metal coating film 6 and the transparent base portion 25. Therefore, it is possible to provide a high luminance compound semiconductor light emitting diode 105.

In the compound semiconductor light emitting diode 105 according to the embodiment of the present invention, since the transparent oxide layer 88 has a conductive structure, it is not necessary to remove the transparent oxide layer on the second ohmic electrode 5 using a photolithography, and thus it is possible to simplify the manufacturing process.

### Sixth Embodiment

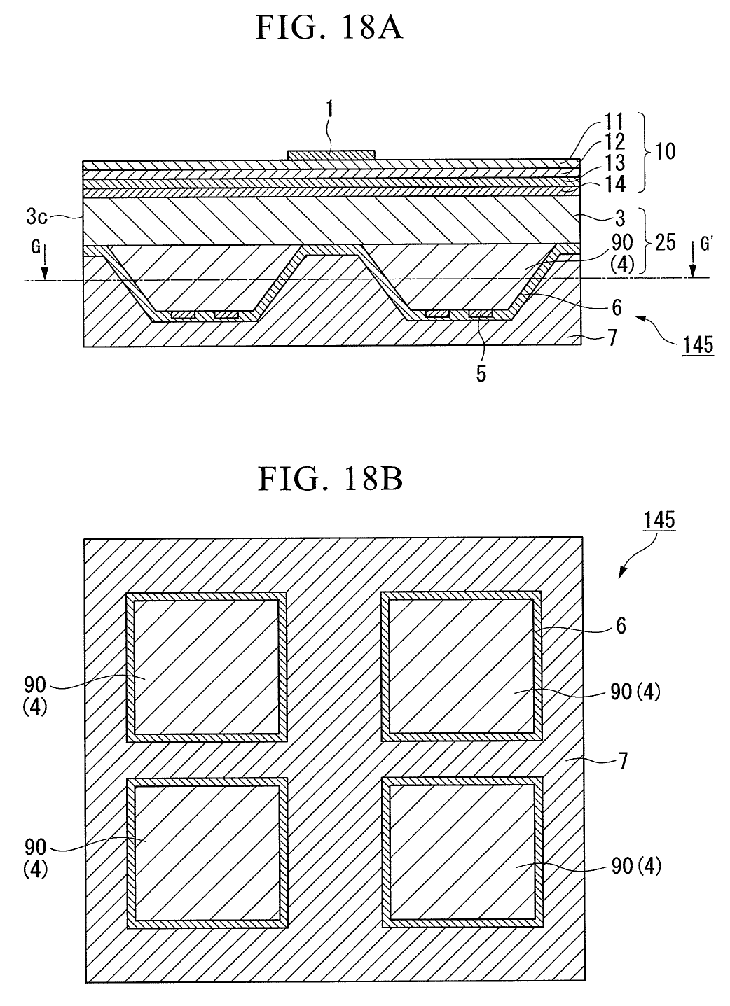

FIGS. 18A and 18B illustrate an exemplary compound semiconductor light emitting diode according to still further another embodiment of the present invention, in which FIG. 18A is a schematic cross-sectional view, and FIG. 18B is a schematic plan cross-sectional view along line G-G′.

A compound semiconductor light emitting diode 145 according to this embodiment of the present invention is similar to the compound semiconductor light emitting diode 101 according to the first embodiment except that 2 (horizontal)×2 (vertical) mesas 90 are arranged on the transparent base portion 25.

In this manner, a plurality of mesas 90 may be proved in the transparent base portion 25. If a plurality of the mesas 90 is provided, the inclined side face 90d of the mesa 90 is widened, and it is possible to effectively reflect the sidelight propagating to the side direction 3c of the compound semiconductor light emitting diode 145 into the front direction f of the compound semiconductor light emitting diode 145. Therefore, since the intensity of light output to the front direction f of the compound semiconductor light emitting diode 145 increases, it is possible to obtain the compound semiconductor visible light emitting diode 145 having improved light emission efficiency with respect to the front direction f.

When a plurality of the mesas 90 is internally provided in the compound semiconductor light emitting diode 145, it is preferable that the mesas 90 are symmetrically arranged with respect to the center of the planary shape of the compound semiconductor light emitting diode 145. For example, the mesas 90 are point-symmetrically arranged with respect to the center point of the planary shape of the compound semiconductor light emitting diode 145. By symmetrically arranging the compound semiconductor, it is possible to obtain a symmetrical distribution of the light emission intensity with respect to the front direction f of the compound semiconductor light emitting diode 145. Therefore, it is possible to obtain an ideal orientation characteristic in which the light emission intensity is maximized with respect to the front direction f of the compound semiconductor light emitting diode 145.

In addition, the electrode structures shown in FIGS. 3 to 11 may be used as the second ohmic electrode 5. An optimal electrode structure is selected considering the desired light emitting diode characteristics and productivity.

The compound semiconductor light emitting diode 145 according to this embodiment of the present invention is similar to the light emitting diode 101 according to the first embodiment except that four compound semiconductors of hexahedrons having an isosceles trapezoidal cross-sectional shape are formed. Therefore, it is possible to obtain the same effects as those of the first embodiment.

In the compound semiconductor light emitting diode 145 according to an embodiment of the present invention, a plurality of the mesas 90 is provided on an opposite side of the one surface 25a of the transparent base portion 25. Therefore, by effectively reflecting light to the front direction f using a plurality of mesas 90 as a reflection mirror, it is possible to improve the light emission efficiency of the compound semiconductor light emitting diode 145.

In the compound semiconductor light emitting diode 145 according to this embodiment of the present invention, a plurality of mesas 90 is symmetrically arranged with respect to the center of the transparent base portion 25 as seen in a plan view. Therefore, by improving planary regularity of light and effectively reflecting the light to the front direction f, it is possible to improve regularity of the light emission intensity of the compound semiconductor light emitting diode 145.

### Seventh Embodiment

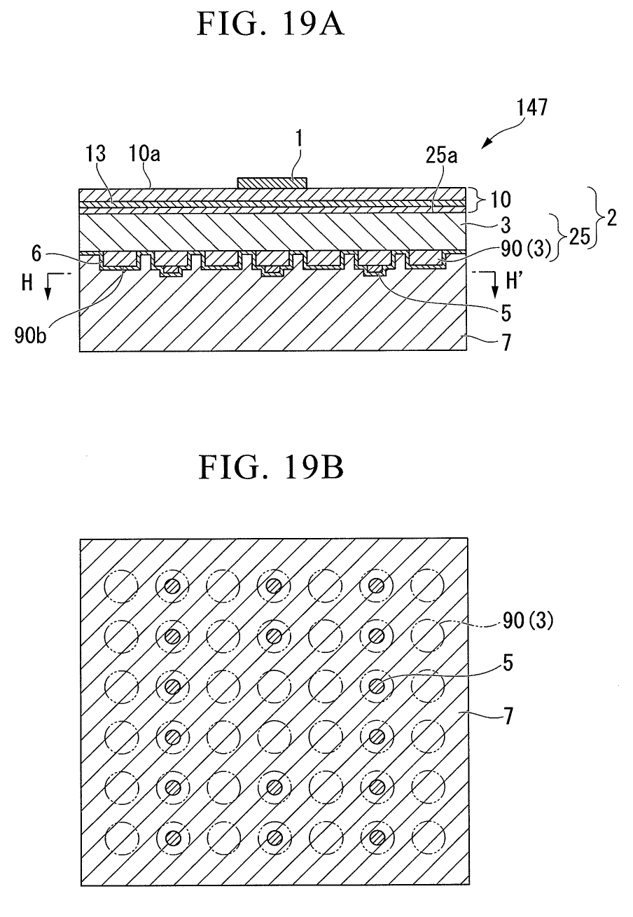

FIGS. 19A and 19B illustrate an exemplary compound semiconductor light emitting diode according to still further another embodiment of the present invention, in which FIG. 19A is a schematic cross-sectional view, and FIG. 19B is a schematic plan cross-sectional view along line H-H′ of FIG. 19A. Since the number of mesas 90 is enormously large, the size and number thereof are different from the actual size and number in the drawings.

As shown in FIGS. 19A and 19B, a compound semiconductor light emitting diode 147 according this embodiment of the present invention includes the transparent base portion 25 made of an optically transparent material, the device structure portion 10 that is formed on one surface 25a of the transparent base portion 25 and includes a light emitting layer 13, and the first ohmic electrode 1 that has one polarity and is formed on the face 10a in the front side of the device structure portion 10. In addition, the transparent base portion 25 includes the p-type GaP layer 3 constituting the mesa 90. In addition, a cylindrical mesa 90 is formed on the opposite side to the one surface 25a of the transparent base portion 25.

The mesas 90 having a fine cylindrical shape are arranged in a matrix pattern. The mesa 90 has, for example, a height of 1 μm and a diameter of 2 μm, and an interval between the centers of the mesas 90 is set to 3 μm. Therefore, approximately 10,000 mesas 90 are formed on a chip having an area of approximately 300 μm². Such mesas 90 are formed, for example, using a dry etching method.

In addition, the second ohmic electrodes 5 having a different polarity from that of the lower bottom face 90b of the mesa 90 are formed on other areas than the transparent area of the first ohmic electrode 1 at a ratio of 1/36.

In addition, the metal coating film 6 is formed to cover the second ohmic electrode 5 and the lower bottom face 90b of the mesa 90. The structure of the metal coating film 6 may be formed by stacking, for example, ITO, silver (Ag), tungsten (W), platinum (Pt), gold (Au), and eutectic AuSn. For example, the ITO has a thickness of 0.1 μm, the Ag has a thickness of 0.1 μm, the W has a thickness of 0.1 μm, the Ni has a thickness of 0.1 μm, the Cu for planarization of the unevenness has a thickness of 1.5 μm, the Au has a thickness of 0.5 μm, and the AuSn has a thickness of 1 μm. The Cu included in this metal coating film 6 is preferably formed using a plating method in order to planarize the height difference of the fine unevenness of the semiconductor layer.

Furthermore, the metallic pedestal portion 7 is formed to cover the metal coating film 6. The pedestal portion 7 is obtained by sequentially stacking molybdenum (Mo), copper (Cu), Mo, Pt, and Au from the side corresponding to the bottom face of the light emitting diode. For example, the Cu has a thickness of 30 μm, the Mo has a thickness of 25 μm, the Cu has a thickness of 30 μm, the Pt has a thickness of 0.1 μm, and the Au has a thickness of 0.5 μm.

In this manner, the pedestal portion 7 is preferably made of a material having a layer structure containing Cu and Mo. Since the pedestal portion 7 has a layer structure containing Cu, it is possible to provide thermal conductivity equal to or higher than 200 W/mK and provide the compound semiconductor light emitting diode having the pedestal portion 7 having a high heat dissipation capability. Furthermore, as a result, the heat can be effectively dissipated, and light can be emitted with a high luminance.

In addition, since the pedestal portion 7 has a Cu—Mo layer structure in which Cu having a high thermal expansion coefficient is interposed between Mo having a thermal expansion coefficient nearly equal to that of the compound semiconductor layer 2, thermal expansion of Cu can be suppressed by Mo, and a thermal expansion rate of 3 to 7 ppm/K can be obtained. Therefore, when the metal coating film 6 and the metal substrate of the pedestal portion 7 are eutectically bonded in the process of forming the pedestal portion 7 which will be described below, they can be bonded without thermally expanding the metal substrate. Therefore, it is possible to manufacture the compound semiconductor light emitting diode with an excellent accuracy.

The thermal expansion rate of the pedestal portion 7 is preferably set to ±20% of the thermal expansion rate of the compound semiconductor layer 2. As a result, when the metal coating film 6 and the metal substrate of the pedestal portion 7 are eutectically bonded, they can be bonded without thermally expanding the metal substrate. Therefore, it is possible to manufacture the compound semiconductor light emitting diode with an excellent accuracy.

In addition, the pedestal portion 7 is formed by bonding the metal substrate to the metal coating film 6 formed to cover the mesa 90 using a metal eutectic method. Hereinafter, an exemplary formation method thereof will be described.

First, as the aforementioned metal substrate, for example, a metal substrate made of Cu (30 μm)/Mo (25 μm)/Cu (30 μm) having a total thickness of 85 μm is prepared. For example, the thermal conductivity of the aforementioned metal substrate becomes 250 W/mK, and the thermal expansion rate becomes 6 ppm/K.

Next, a film containing Pt and Au is formed on the surface of the aforementioned metal substrate using a sputtering method. For example, Pt has a thickness of 0.1 μm, and Au has a thickness of 0.5 μm. By forming the layer containing Pt and Au, it is possible to reduce erroneous bonding between the metal substrate and the metal film 6 in the subsequent eutectic bonding process.

Next, the surfaces of the AuSn layer of the metal coating film 6 and the Au layer of the metal substrate are superimposed and eutectically bonded by heating them at a temperature of 330° C. under a load of 100 g/cm². Since the height difference caused by the fine unevenness of the semiconductor layer is planarized by the Cu layer formed using a plating method, it can be readily bonded to the metal substrate. In this case, by using the pedestal portion 7 having a low thermal expansion coefficient of 5 ppm, it is possible to perform the bonding with a low stress even under a high temperature.

Finally, a part of the metal substrate is cut out using a laser beam condensed into 0.7 mm² to provide chips so that the compound semiconductor light emitting diode is manufactured.

Since the aforementioned compound semiconductor light emitting diode uses the pedestal portion 7 having a high thermal conductivity of 250 W/mK, it is possible to provide a high luminance compound semiconductor light emitting diode having an excellent heat dissipation capability.

In the compound semiconductor light emitting diode 147 according to this embodiment of the present invention, since the device structure portion 10 is formed on one surface 25a of the transparent base portion 25, the light emitted from the device structure portion is transmitted through the transparent base portion 25 and then reflected to the front direction at the metal coating film 6. Therefore, it is possible to provide a compound semiconductor light emitting diode having an excellent light output capability to the front direction (external view direction).

In the compound semiconductor light emitting diode 147 according to this embodiment of the present invention, since the metallic pedestal portion 7 is attached to the transparent base portion 25 through the metal coating film 6, it is possible to address the poor mounting stability of the light emitting diode of the related art which is difficult to autonomously stand erect because a bottom face area is reduced by cutting out the side face. Meanwhile, it is possible to stably provide the compound semiconductor light emitting diode having an excellent heat dissipation capability.

In the compound semiconductor light emitting diode 147 according to this embodiment of the present invention, since the pedestal portion 7 is made of a material including a Cu—Mo layer structure having a thermal conductivity equal to or larger than 200 W/mK, it is possible to provide a high luminance compound semiconductor light emitting diode having an excellent heat dissipation capability.

Since the compound semiconductor light emitting diode 147 according to this embodiment of the present invention is made of a material including a Cu—Mo layer structure in which the thermal expansion rate of the pedestal portion 7 is within ±20% of the thermal expansion rate of the compound semiconductor layer 2, it is possible to manufacture the compound semiconductor light emitting diode bonded at a high temperature with a low stress and simplify the manufacturing process.

Since the compound semiconductor light emitting diode 147 according to this embodiment of the present invention is made of a material including a Cu—Mo layer structure such that the thermal expansion rate of the pedestal portion 7 becomes 3 to 7 ppm/K, it is possible to manufacture the compound semiconductor light emitting diode bonded at a high temperature with a low stress and an excellent accuracy, and simplify the manufacturing process.

### Eighth Embodiment 8

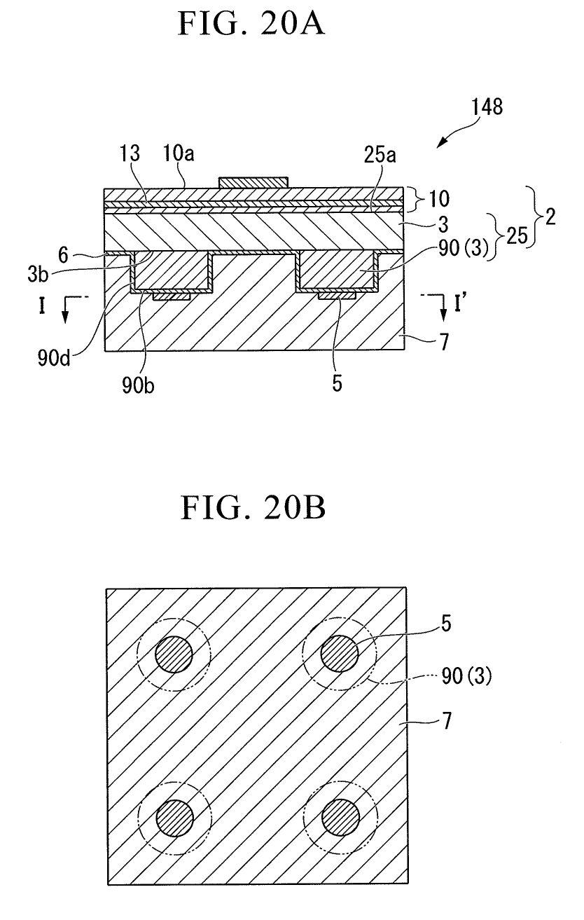

FIGS. 20A and 20B illustrate an exemplary compound semiconductor light emitting diode according to still further another embodiment of the present invention, in which FIG. 20A is a schematic cross-sectional view, and FIG. 20B is a schematic plan cross-sectional view along line I-I′ of FIG. 20A.

As shown in FIGS. 20A and 20B, the compound semiconductor light emitting diode 148 according to the embodiment of the present invention includes the transparent base portion 25 made of an optically transparent material, the device structure portion 10 formed on one surface 25a of the transparent base portion 25 and including the light emitting layer 13, and the first ohmic electrode 1 formed on the face 10a in the front side of the device structure portion 10 and having one polarity. In addition, the transparent base portion 25 is made of the p-type GaP layer 3 included in the mesa 90. In addition, a cylindrical mesa 90 is formed on the opposite side to the one surface 25a of the transparent base portion 25.

The fine cylindrical mesas 90 are arranged in a matrix shape. As the size of the mesa 90, for example, the height is set to 3 μm and the diameter is set to 50 μm. the angle between the inclined side face 90d of the mesa 90 and the other surface 3b of the p-type GaP layer 3 is set to 88°. In addition, the interval between ther centers of the mesas 90 is set to 100 μm. Such mesas 90 are formed, for example, using a dry etching method.

In addition, on the area other than the transparent area of the first ohmic electrode 1, the second ohmic electrode 5 having a different polarity from that of the lower bottom face 90b of the mesa 90 is formed. The second ohmic electrode 5 is set to, for example, 30 μm.

In addition, the metal coating film 6 is formed to cover the second ohmic electrode 5 and the lower bottom face 90b. The structure of the metal coating film 6 is obtained by stacking, for example, ITO and Ag. The thickness of ITO is set to 0.3 μm, and the thickness of Ag is set to 0.5 μm. Each layer is formed, for example, using a sputtering method.

Furthermore, the pedestal portion 7 containing Mo, nickel (Ni), and Cu is formed to cover the metal coating film 6. For example, the thickness of Mo is set to 0.8 μm, the thickness of Ni is set to 0.5 μm, and the thickness of Cu is set to 70 μm.

In this manner, since the pedestal portion 7 is made of a material including a Cu—Mo layer structure, it is possible to obtain a thermal conductivity of 350 W/mk and provide a compound semiconductor light emitting diode including the pedestal portion 7 having a high heat dissipation capability. Furthermore, as a result, it is possible to effectively dissipate the heat and emit light with a high luminance.

In addition, in the pedestal portion 7, Mo and Ni are formed using a sputtering method, and then, a thick Cu layer is formed using an electrolytic plating method. Finally, the compound semiconductor light emitting diode chips are manufactured by cutting out them using a laser focused in an area of 0.7 mm².

In the compound semiconductor light emitting diode 148 according to this embodiment of the present invention, the pedestal portion 7 has a thermal conductivity equal to or larger than 200 W/mK and is made of a material including a Cu—Mo layer structure. Therefore, it is possible to provide a high luminance compound semiconductor light emitting diode with an excellent heat dissipation capability.

### INDUSTRIAL APPLICABILITY

The present invention can be used in the optical industry demanding a light emitting diode, particularly, a large-sized and high luminance light emitting diode bonded to the transparent bonding substrate. The present invention can provide a novel light emitting diode having a large size, a high luminance, and a high reliability, and can be used in various display lamps.

1. A compound semiconductor light emitting diode comprising:
a device structure portion formed on one surface of a transparent base portion made of an optically transparent material, the device structure portion including
a compound semiconductor layer having a first conductivity type,
a light emitting layer made of mixed crystals of aluminum gallium indium phosphide (having a composition of (Al_{X}Ga_{1-X})_{0.5}In_{0.5}P; 0≦X<1) and having a first conductivity type or a conductivity type opposite to the first conductivity type, and
a compound semiconductor layer having a conductivity type opposite to the first conductivity type; and
a first ohmic electrode formed on the device structure portion and having a single polarity,
wherein a second ohmic electrode is formed on an opposite side of the one surface of the transparent base portion, a metal coating film is formed to cover the second ohmic electrode, and a metallic pedestal portion covering the metal coating film is formed to electrically connect to the second ohmic electrode.

2. The compound semiconductor light emitting diode according to claim 1, wherein a mesa having a vertical cross-sectional shape of an inverted isosceles trapezoidal shape is formed on an opposite side of the one surface of the transparent base portion, the mesa has a lower bottom face and an inclined side face, a second ohmic electrode is formed on the lower bottom face, and a metal coating film is formed to cover the second ohmic electrode, the lower bottom face, and the inclined side face.

3. The compound semiconductor light emitting diode according to claim 1, wherein the transparent base portion is made of a growth base layer.

4. The compound semiconductor light emitting diode according to claim 1, wherein the transparent base portion includes a growth base layer and a transparent bonding substrate bonded to the growth base layer.

5. The compound semiconductor light emitting diode according to claim 4, wherein the transparent bonding substrate has the same conductivity type as that of the growth base layer.

6. The compound semiconductor light emitting diode according to claim 4, wherein a face of the transparent bonding substrate, bonded to the growth base layer, is a mirror-polished face having a roughness of 0.10 to 0.20 nm as a root-mean-square value.

7. The compound semiconductor light emitting diode according to claim 2, wherein an inclination angle of the inclined side face is equal to or larger than 10° and equal to or smaller than 45° with respect to a normal line to one surface of the transparent base portion.

8. The compound semiconductor light emitting diode according to claim 2, wherein the inclined side face is a roughened face having unevenness equal to or larger than 0.1 μm and equal to or smaller than 10 μm as a height difference.

9. The compound semiconductor light emitting diode according to claim 2, wherein the lower bottom face is a roughened face having unevenness equal to or larger than 0.1 μm and equal to or smaller than 10 μm as a height difference.

10. The compound semiconductor light emitting diode according to claim 2, wherein an opposite side of the one surface of the transparent base portion has a plurality of mesas.

11. The compound semiconductor light emitting diode according to claim 10, wherein a plurality of the mesas is symmetrically positioned with respect to a center of the transparent base portion as seen in a top plan view.

12. The compound semiconductor light emitting diode according to claim 2, wherein a plurality of the second ohmic electrodes is provided on the lower bottom face.

13. The compound semiconductor light emitting diode according to claim 1, wherein the metal coating film is made of a material different from the second ohmic electrode.

14. The compound semiconductor light emitting diode according to claim 1, wherein the metal coating film has a reflectance equal to or larger than 80% with respect to light irradiated from the device structure portion and is made of a material containing any one of silver, aluminum, or platinum.

15. The compound semiconductor light emitting diode according to claim 1, wherein the metal coating film is formed to cover an opposite side of the one surface of the transparent base portion.

16. The compound semiconductor light emitting diode according to claim 1, wherein the pedestal portion has a thermal conductivity equal to or higher than 200 W/mK and is made of a material containing any one of copper, aluminum, gold, or platinum.

17. The compound semiconductor light emitting diode according to claim 16, wherein the pedestal portion has a thermal conductivity equal to or higher than 200 W/mK and is made of a material containing a layer structure of copper or molybdenum.

18. The compound semiconductor light emitting diode according to claim 16, wherein a thermal expansion rate of the pedestal portion is within ±20% of a thermal expansion rate of the compound semiconductor layer and is made of a material containing a layer structure of copper or molybdenum.

19. The compound semiconductor light emitting diode according to claim 16, wherein a thermal expansion rate of the pedestal portion is 3 to 7 ppm/K and is made of a material containing a layer structure of copper or molybdenum.

20. The compound semiconductor light emitting diode according to claim 1, wherein a transparent oxide layer is inserted between the metal coating film and the transparent base portion.

21. The compound semiconductor light emitting diode according to claim 20, wherein the transparent oxide layer has conductivity.
